(19) United States
(12) Patent Application Publication
(10) Pub. No.: US 2023/0354566 A1
(43) Pub. Date: Nov. 2, 2023

(54) ULTRA-HIGH MOLECULAR WEIGHT POLYETHYLENE MULTILAYERS FOR VR/AR/MR THERMAL MANAGEMENT

(71) Applicant: Meta Platforms Technologies, LLC, Menlo Park, CA (US)

(72) Inventors: Arman Boromand, Issaquah, WA (US); Giti Karimi Moghaddam, Saratoga, CA (US); Ryan Fleming, Oakland, CA (US); Michael Nikkhoo, Saratoga, CA (US); Alex Ockfen, Bothell, WA (US); Sheng Ye, Redmond, WA (US); Andrew John Ouderkirk, Kirkland, WA (US); Hongtao Guo, Redmond, WA (US)

(21) Appl. No.: 18/167,052

(22) Filed: Feb. 9, 2023

Related U.S. Application Data
(60) Provisional application No. 63/336,187, filed on Apr. 28, 2022.

(51) Int. Cl. H05K 7/20; B32B 7/12; B32B 27/32; B32B 27/08; B32B 7/035

(52) U.S. Cl. CPC H05K 7/20963; B32B 7/12; B32B 27/32; B32B 27/08; B32B 7/035; B32B 2551/00; B32B 2250/242; B32B 2307/414; B32B 2307/302; B32B 2307/54; B32B 2307/732; B32B 2307/204; B32B 2307/206; B32B 2307/516; B32B 2307/518

(57) ABSTRACT

A polymer laminate includes a plurality of ultra-high molecular weight polyethylene thin films, where each polyethylene thin film has an in-plane thermal conductivity of at least approximately 5 W/mK and an in-plane elastic modulus of at least approximately 20 GPa. The polymer laminate may be incorporated into an eyewear device and may be configured to disperse heat during operation thereof in a manner effective to improve the functionality and/or wearability of the device.

### CROSS-REFERENCE TO RELATED APPLICATION

This application claims the benefit of priority under 35 U.S.C. § 119(e) of U.S. Provisional Application No. 63/336,187, filed Apr. 28, 2022, the contents of which are incorporated herein by reference in their entirety.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 is a schematic illustration of an orthogonal consecutive stretching (OCS) apparatus and method for deforming and orienting a polymer thin film according to some embodiments.

FIG. 2 is a schematic illustration of an extrusion system for forming a polymer thin film or multilayer according to certain embodiments.

FIG. 3 is a schematic view of an example thin film orientation system for manufacturing an anisotropic polymer thin film according to some embodiments.

FIG. 4 is a schematic view of a thin film orientation system for manufacturing an anisotropic polymer thin film according to further embodiments.

FIG. 5 shows (A-B) cross-sectional views of example ultra-high molecular weight polyethylene-containing multilayers, and (C) a top-down plan view showing a clocked relationship between PE layers in an example bilayer structure according to various embodiments.

FIG. 6 is a schematic illustration of (A) a virtual reality headset, and associated thermal profiles (B) for the headset without an integrated ultra-high molecular weight polyethylene multilayer and (C) for the headset with an integrated ultra-high molecular weight polyethylene multilayer according to some embodiments.

FIG. 7 shows an experimental setup for evaluating the thermal management properties of an ultra-high molecular weight polyethylene (UHMWPE) thin film according to some embodiments.

FIG. 8 shows heat dissipation plots for the experimental setup of FIG. 7 for (A) 200 mW applied power and (B) 500 mW applied power according to various embodiments.

FIG. 9 shows optical micrographs of virtual reality headsets integrated with various ultra-high molecular weight polyethylene thin film structures according to certain embodiments.

FIG. 10 shows an experimental setup for evaluating the thermal management properties of an ultra-high molecular weight polyethylene (UHMWPE) thin film or multilayer according to further embodiments.

FIG. 11 is a Table summarizing the thermal dissipation properties for the ultra-high molecular weight polyethylene thin film structures shown in FIGS. 9 and 10 according to some embodiments.

FIG. 12 is a further Table summarizing the thermal dissipation properties for the ultra-high molecular weight polyethylene thin film structures shown in FIGS. 9 and 10 according to further embodiments.

FIG. 13 shows optical micrographs of virtual reality headsets integrated with thermally dissipative layers of (A) consolidated polybenzoxazole fibers, (B) a pitch carbon fiber (PCF) composite, (C) a polyethylene fiber composite, and (D) consolidated ultra-drawn ultra-high molecular weight polyethylene according to certain embodiments.

FIG. 14 shows (A) a thermal profile and (B) infrared imaging of a virtual reality headset overlaid with a polycarbonate composite according to some embodiments.

FIGS. 15A-D are infrared images of virtual reality headsets integrated with an ultra-high molecular weight polyethylene fiber mat composite for different heater temperatures according to various embodiments.

FIGS. 16A-D are thermal profiles for the virtual reality headsets of FIGS. 15A-D according to various embodiments.

FIG. 17 is a thermal profile of a virtual reality headset front cover made from isotropic ultra-high molecular weight polyethylene according to some embodiments.

FIG. 18 is a plot of maximum temperature difference versus thermal conductivity for various heat dissipative substrates at different input thermal power and surface emissivity according to certain embodiments.

FIG. 19 is a plot of maximum temperature difference versus input power for an ultra-high molecular weight polyethylene substrate according to some embodiments.

FIG. 20 is a plot of maximum temperature difference versus thermal conductivity for example heat dissipative substrate configurations according to some embodiments.

FIG. 21 is a plot of elastic modulus versus consolidation temperature for an 8-ply uni-directional stack of ultra-high molecular weight polyethylene according to certain embodiments.

FIG. 22 is a plot of elastic modulus versus consolidation pressure for an 8-ply uni-directional stack of ultra-high molecular weight polyethylene according to certain embodiments.

FIG. 23 is a Table summarizing differential scanning calorimetry (DSC) data for different heat dissipative material formation conditions according to some embodiments.

FIG. 24 illustrates thermal simulations for (A) opaque and (B) transparent headset enclosure configurations according to certain embodiments.

FIG. 25 is a Table summarizing system data for the thermal simulations of FIG. 24 according to some embodiments.

FIG. 26 is an illustration of exemplary augmented-reality glasses that may be used in connection with embodiments of this disclosure.

FIG. 27 is an illustration of an exemplary virtual-reality headset that may be used in connection with embodiments of this disclosure.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

Polymer materials may be incorporated into a variety of different optic and electro-optic systems, including active and passive optics and electroactive devices. Lightweight and conformable, one or more polymer layers may be incorporated into wearable devices such as smart glasses and are attractive candidates for emerging technologies including virtual reality/augmented reality/mixed reality devices where a comfortable, adjustable form factor is desired.

Virtual reality (VR), augmented reality (AR), and mixed reality (MR) eyewear devices or headsets, for instance, may enable users to experience events, such as interactions with people in a computer-generated simulation of a three-dimensional world or viewing data superimposed on a real-world view. By way of example, superimposing information onto a field of view may be achieved through an optical head-mounted display (OHMD) or by using embedded wireless glasses with a transparent heads-up display (HUD) or augmented reality (AR) overlay. VR/AR/MR eyewear devices and headsets may be used for a variety of purposes. For example, governments may use such devices for military training, medical professionals may use such devices to simulate surgery, and engineers may use such devices as design visualization aids.

These and other applications may leverage one or more characteristics of polymer materials, including refractive index to manipulate light, thermal conductivity to manage heat, and mechanical strength and toughness to provide light-weight structural support.

In accordance with various examples, VR/AR/MR headsets and other devices such as wireless chargers and enclosures for personal electronics may typically include multiple heat-generating components located in a compact form factor. The operational efficiency and performance of such devices may benefit from one or more control systems, including thermal management systems, that are configured to monitor and/or beneficially impact one or more of a power supply, a rendered image, data I/O, device lifetime, user comfort and safety, etc. In many comparative devices, lenses may include high modulus, high strength optical grade polymers, such as polycarbonates and acrylics. These materials are thermal insulators, however, and may allow heat to accumulate in, and proximate to, the lenses, which may adversely affect function as well as the experience of a user.

As disclosed herein, stretched ultra-high molecular weight polyethylene and related polymer compositions may be used as a thermally conductive layer, either laminated over comparative lens materials or as a free-standing lens, and may be configured to dissipate heat. Moreover, in VR/AR/MR systems, the performance requirements of ultra-high molecular weight polyethylene may extend beyond thermal conductivity, and may include RF transparency, high modulus, high strength, and/or high optical transmissivity and clarity. As will be appreciated, the formation of a polyethylene-based composition may be challenged by the competing attributes of optical clarity and mechanical strength in a stretched thin film.

Notwithstanding recent developments, it would be advantageous to provide optical quality and mechanically robust polymer thin films suitable for use in various optical systems including display systems for artificial reality applications. Applicants have shown that decreased chain entanglement and associated improvements in crystallization as well as the orientation of crystallites in polyethylene-based compositions can yield highly thermally conductive polyethylene-based thin films, which may additionally have a desired combination of optical and mechanical properties.

The instant disclosure is thus directed generally to thermally conductive polymer thin films having high mechanical strength and RF transparency and their methods of manufacture, and more specifically to thermally dissipative polyethylene-based polymer multilayers.

The optical, thermal, and mechanical response of a polymer thin film may be determined by its chemical composition, the chemical structure of the polymer repeat unit, its density and extent of crystallinity, as well as the alignment of the crystals and/or polymer chains throughout the polymer matrix. Among these factors, the crystal or polymer chain alignment may dominate. In crystalline or semi-crystalline polymer thin films, an optical, thermal, or mechanical property or condition may be correlated to the degree or extent of crystal orientation, whereas the degree or extent of chain entanglement may create comparable optical, thermal, or mechanical properties in polymer thin films including an amorphous phase.

An applied stress may be used to form a preferred alignment of crystals or polymer chains within a polymer thin film and induce a corresponding modification of the optical, thermal, and/or mechanical properties along different directions of the film. As disclosed further herein, during processing where a polymer thin film is stretched to induce a preferred alignment of crystals/polymer chains and an attendant modification of the refractive index/birefringence, thermal, and mechanical properties, Applicants have shown that approaches to forming an anisotropic material may include modifying the composition of the polymer as well as the kinetics of the stretching process. Modification of the polymer composition may, in some examples, include the addition of a low molecular weight additive.

Stretching may include the application of a uniaxial or biaxial stress. Stretching may include a single act of stretching or plural, successive stretching events, such as along different in-plane directions of a polymer thin film. An act of stretching may be velocity limited or strain rate limited. In some embodiments, a polymer thin film may be stretched at a variable or constant velocity. In some embodiments, the polymer may be stretched using a variable strain rate or a constant strain rate (e.g., 0.5 s⁻¹, 1 s⁻¹, 5 s⁻¹, or 10 s⁻¹, including ranges between any of the foregoing values). By way of example, the strain rate may decrease throughout an act of stretching and/or amongst different stretching events from an initial strain rate (e.g., 5 s⁻¹) to a final strain rate (e.g., 0.5 s⁻¹).

In accordance with particular embodiments, Applicants have developed a polymer thin film manufacturing method for forming an optical quality polyethylene (PE) thin film having desired optical clarity and strength. Applicants have demonstrated that high quality, high performance single layer and multilayer polymer thin films having improved drawability and enhanced optical, thermal, and mechanical properties may be formed by implementing stretching processes throughout one or more stages of thin film manufacture, including the acts of forming, pre-orienting, and final stretching.

Polymer thin films may be formed using casting operations such as melt extrusion, compression molding, solvent casting, gel casting, and the like. Applicants have demonstrated that enhanced drawability may be achieved by tuning one or more of the draw temperature and the draw rate of a cast polymer thin film. In some examples, the draw temperature may be correlated to the thin film's primary (glass, or alpha) relaxation and/or its low temperature (beta) relaxation.

In some embodiments, polyethylene may be provided in particulate or powder form. Example polyethylene powders may have a particle size distribution (d90) greater than approximately 50 micrometers, e.g., greater than 50, 100, 200, or 300 micrometers, including ranges between any of the foregoing values.

A low molecular weight additive may be provided in particulate or powder form, and may have a particle size distribution (d90) less than approximately 30 micrometers, e.g., 5, 10, 15, 20, or 25 micrometers, including ranges between any of the foregoing values. An additive may include a wax or waxy material, for example.

In some embodiments, particulate or powdered polyethylene may be mixed with a particulate or powdered wax in a continuous mixer (LCM) at any suitable temperature. For instance, a mixing temperature may be less than, equal to, or greater than a melting temperature of the wax (additive). The mixing may be adapted to impregnate the polyethylene with the wax to form a homogeneous mixture prior to casting.

In some examples, a mixture of “unentangled” polyethylene and low molecular weight additive may be extruded at a temperature less than approximately 140° C. (e.g., 120° C. or 130° C.) and above the melting point of the additive to form a polymer thin film. An extruded thin film may have a thickness of less than approximately 2 mm (e.g., 500 micrometers, 750 micrometers, or 1 mm, including ranges between any of the foregoing values) and a porosity of less than approximately 10% (e.g., less than 5%, less than 2%, or less than 1%).

In example melt extrusion methods, the melt may undergo pre-orientation with a draw down ratio (DDR) of at least approximately 1, e.g., approximately 1, approximately 2, approximately 3, or approximately 4, including ranges between any of the foregoing values. The melt may be collected on a chilled roller. The roller temperature may be less than (e.g., at least approximately 10° C. less than) the lowest melting point of any additive included in the melt. The cast polymer may undergo a machine direction orientation (MDO) process to form a hard cast film having a draw ratio along the machine direction (MDX) of at least approximately 2, e.g., at least approximately 2, at least approximately 4, or at least approximately 6, including ranges between any of the foregoing values.

According to further embodiments, a polymer thin film may be formed via gel casting from a dilute solution including a polymer composition and a first solvent followed by removal of the solvent. Example solvents include poor solvents such as mineral oils, paraffin oil, stearic acid, p-xylene, dodecanol, and the like. The first solvent may be removed prior to, during, and/or after the act(s) of stretching. The first solvent may be removed directly by evaporation, or through contact with a miscible second solvent followed by evaporation of the resulting co-solvent.

A cast polymer thin film may be stretched using single or multiple stretching events. Some stretching processes may include two successive stretching events. For instance, orthogonal consecutive stretching (OCS) may be used to develop structural fingerprints, such as smaller lamellar thicknesses and higher degrees of polymer chain orientation at draw ratios less than the draw ratios used to achieve similar structural fingerprints via comparative single stretching (SS) or parallel consecutive stretching (PCS) techniques. Orthogonal consecutive stretching may include first stretching a polymer thin film along a first in-plane axis, and then subsequently stretching the polymer thin film along a second in-plane axis that is orthogonal to the first in-plane axis.

In an example OCS method, a cast polymer thin film may be stretched along a first in-plane axis to a stretch ratio of up to approximately 4 (e.g., 2, 3, or 4, including ranges between any of the foregoing values) with an attendant relaxation in the cross-stretch direction having a relaxation ratio of at least approximately 0.2 (e.g., 0.2, 0.3, 0.4, or 0.5, including ranges between any of the foregoing values). Subsequently, the polymer thin film may be stretched along a second in-plane axis orthogonal to the first in-plane axis to a stretch ratio of at least approximately 7 (e.g., 7, 10, 20, 30, 40, 50, or 60, including ranges between any of the foregoing values) with a relaxation ratio in the cross-stretch direction of at least approximately 0.2 (e.g., 0.2, 0.3, 0.4, or 0.5, including ranges between any of the foregoing values).

In some examples, the draw ratio in the first stretching step may be less than the draw ratio in the second stretching step. According to further embodiments, the temperature of the polymer thin film during the second stretching step may be greater than the polymer thin film temperature during the first stretching step. For instance, the temperature during the second stretching step may be at least approximately 5° C. greater than the temperature during the first stretching step (e.g., 5, 10, 15, or 20° C. greater, including ranges between any of the foregoing values).

In some embodiments, a polymer thin film may be heated and stretched along a first direction, cooled, and then heated and stretched along a second direction. In some embodiments, a polymer thin film may be heated and stretched along a first direction, cooled, and then heated and stretched again along the first direction. Following the second stretching step, the polymer thin film may be cooled. The acts of cooling may immediately follow the first (or second) stretching steps, where the polymer thin film may be cooled within approximately 10 seconds following completion of the first (or second) stretching step. In some examples, the temperature of the polymer thin film during an act of stretching may be greater than the glass transition temperature of the polymer. In some examples, the temperature of the polymer thin film during an act of stretching may be less than, equal to, or greater than the melting onset temperature of the polymer.

In various examples, the extent of relaxation perpendicular to the stretch direction may be approximately equal to the square root of the stretch ratio in the stretch direction. In some embodiments, the extent of relaxation may be substantially constant throughout the stretching process(es). In further embodiments, the extent of relaxation may decrease, with greater relaxation associated with the beginning of a stretch step and lesser relaxation associated with the end of a stretch step.

An example polymer may include ultra-high molecular weight polyethylene (UHMWPE). According to some embodiments, the optical properties of UHMWPE may be improved in conjunction with the processing methods disclosed herein by decreasing or eliminating surface and/or bulk defects. In some embodiments, one or more low melting point additives may be incorporated into the polymer matrix of a polymer thin film.

Example polyethylene materials include high molecular weight polyethylene, high density polyethylene, ultra-high molecular weight polyethylene, as well as derivatives and mixtures thereof, and may have a molecular weight (e.g., weight-averaged molecular weight) of at least approximately 100,000 g/mol, e.g., at least approximately 100,000 g/mol, or at least approximately 250,000 g/mol. Ultra-high molecular weight polyethylene may have a molecular weight of at least approximately 300,000 g/mol, e.g., approximately 300,000 g/mol, approximately 400,000 g/mol, approximately 500,000 g/mol, approximately 600,000 g/mol, approximately 700,000 g/mol, approximately 800,000 g/mol, approximately 900,000 g/mol, approximately 1,000,000 g/mol, approximately 2,000,000 g/mol, or approximately 5,000,000 g/mol, including ranges between any of the foregoing values.

In some embodiments, a polymer thin film that includes high molecular weight polyethylene may additionally include from approximately 5 wt. % to approximately 50 wt. % (e.g., approximately 5 wt. %, approximately 10 wt. %, approximately 20 wt. %, or approximately 50 wt. %, including ranges between any of the foregoing values) of a secondary polymer having a molecular weight of less than approximately 50,000 g/mol (e.g., less than approximately 50,000 g/mol, less than approximately 20,000 g/mol, or less than approximately 10,000 g/mol, including ranges between any of the foregoing values). In addition to, or in lieu of, polyethylene, further example polymer compositions include polybenzoxazole.

In some embodiments, a polymer thin film may include a low molecular weight additive. The additive may include a low molecular weight polyethylene or polyethylene oligomer and may constitute from approximately 1 wt. % to approximately 90 wt. % of the polymer matrix forming the polymer thin film. Additives may have good solubility in, and may be index matched with, high molecular weight polyethylene, high density polyethylene, or ultra-high molecular weight polyethylene.

Example additives include one or more of hydrocarbon waxes, e.g., polyethylene-wax molecules or amide waxes, mineral oils, fluoropolymers, etc. If used, polyethylene-wax molecules may have a molecular weight of at least approximately 400 g/mol, e.g., 400, 1000, 2000, or 3000 g/mol, including ranges between any of the foregoing values. The wax content may be at least approximately 2 wt. %, e.g., 2, 5, 10, 20, 50, or 80 wt. %, including ranges between any of the foregoing values. Suitable mineral oils may have a molecular weight of at least approximately 200 g/mol, e.g., 200, 400, or 600 g/mol, including ranges between any of the foregoing values. In some embodiments, up to approximately 1000 ppm (e.g., 200, 400, 600, 800, or 1000 ppm) of a fluoropolymer or other processing aid may be incorporated into the polymer matrix. An additive may be characterized by a refractive index of approximately 1.5 to approximately 1.6, e.g., 1.55.

In some embodiments, an additive incorporated into the polymer matrix may include a photothermal dye. Example photothermal dyes include 2-(2H-benzotriazol-2-yl)-4,6-di-tert-pentylphenol (BZT), azobenzene, coronatine dye, graphene, quaterrylene-based dyes, and metal nanoparticles such as gold nanoparticles, as well as mixtures thereof. A photothermal dye such as azobenzene or metal nanoparticles may be functionalized by ethylene oligomers having a molecular weight of at least approximately 500 g/mol, e.g., 500, 1000, 2000, or 3000 g/mol, including ranges between any of the foregoing values. In some examples, a concentration of a photothermal additive within the polymer matrix may be at least approximately 0.5 wt. %, e.g., 0.5, 1, 2, or 5 wt. %, including ranges between any of the foregoing values. A functionalized photothermal dye may be added to a polymer prior to or during formation of a thin film, which may be stretched to form a dichroic arrangement of dye in the polymer matrix.

In some embodiments, optical and mechanical properties may be specifically targeted, and the polymer thin film may contain approximately 60 wt. % to approximately 90 wt. % of a low molecular weight polyethylene or polyethylene oligomer. In some embodiments, thermal conductivity may be specifically targeted, and the polymer thin film may contain approximately 1 wt. % to approximately 10 wt. % of a low molecular weight polyethylene or polyethylene oligomer.

A thermally conductive additive may have a thermal conductivity of at least approximately 5 W/mK, e.g., 5, 10, 15, 20, 25, 30, 35, 40, 45, 50 W/mK or more, including ranges between any of the foregoing values. Example thermally conductive additives include graphene, borophene, boron nitride (hexagonal-BN), carbon nanotubes, silver nanowires, and metal nanoparticles, such as high aspect ratio metallic nanoparticles. According to some embodiments, the loading of a thermally conductive additive may range from approximately 0.01 wt. % to approximately 1 wt. %. By way of example, phenolic benzotriazoles can form 7C-7C interactions with polymer chains in a polyethylene polymer and enable phonons to pass at extremely low loading amounts without affecting optical quality.

A low molecular weight additive may have a molecular weight of less than approximately 4,000 g/mol, e.g., less than approximately 4,000 g/mol, less than approximately 2,000 g/mol, less than approximately 1,000 g/mol, less than approximately 500 g/mol, or less than approximately 200 g/mol. An example low molecular weight additive may be characterized by a melting temperature (Tₘ) of at least approximately 40° C., e.g., approximately 40° C., approximately 60° C., approximately 80° C., approximately 100° C., or approximately 120° C., including ranges between any of the foregoing values. Reference herein to a melting temperature (Tₘ) may include reference to a temperature corresponding to the onset of melting.

Example polyethylene polymer and oligomer-based additives may include a reactive group such as vinyl, acrylate, methacrylate, epoxy, isocyanate, hydroxyl, amine, and the like. Such additives may be cured in situ, i.e., within a polymer thin film by applying one or more of heat or light, or by reaction with a suitable catalyst.

In some embodiments, plural additives may be used. According to particular embodiments, an original additive can be used during processing of a thin film (e.g., during extrusion, stretching, and/or calendaring). Thereafter, the original additive may be removed such as by washing or evaporation and replaced by a secondary additive. A secondary additive (e.g., various phenolic benzotriazoles) may be index matched to the crystalline polyethylene polymer and may, for example, have a refractive index ranging from approximately 1.45 to approximately 1.6. A secondary additive can be added by soaking the thin film under melting conditions or in a solvent bath. A secondary additive may have a melting point of less than approximately 100° C.

A secondary additive, if used, may be a poor solvent to polyethylene. Example poor solvents include stearic acid or saturated hydrocarbons such as mineral oils (e.g., Kaydol® mineral oil, paraffin oil, Primol™ oil, and the like). The secondary additive may be removed before, during, or after a film stretching process such as by evaporation or solvent exchange.

The presently disclosed polymer thin films may be characterized as optical quality polymer thin films and may form, or be incorporated into, an optical element. Such optical elements may be used in various display devices, such as virtual reality (VR), augmented reality (AR), and mixed reality (MR) glasses and headsets. The efficiency of these and other optical elements may depend on the degree of optical clarity and/or one or more mechanical properties of the polymer thin film.

According to various embodiments, an “optical quality” polymer thin film or an “optical” thin film may, in some examples, be characterized by transmissivity within the visible light spectrum of at least approximately 20%, e.g., 20, 30, 40, 50, 60, 70, 80, 90 or 95%, including ranges between any of the foregoing values, and less than approximately 10% bulk haze, e.g., 0, 1, 2, 4, 6, or 8% bulk haze, including ranges between any of the foregoing values.

A material or element that is “transparent” or “optically transparent” may, for a given thickness, have a transmissivity within the visible light (e.g., 380-750 nm) and/or RF (e.g., 2-20 GHz) spectra of at least approximately 85%, e.g., approximately 85, 90, 95, 97, 98, 99, or 99.5%, including ranges between any of the foregoing values, and less than approximately 5% bulk haze, e.g., approximately 0.1, 0.2, 0.5, 1, 2, or 5% bulk haze, including ranges between any of the foregoing values. Transparent materials will typically exhibit very low optical absorption and minimal optical scattering. An RF transparent polyethylene thin film or multilayer, for example, may minimally affect the antennae performance of a device or system.

As used herein, the terms “haze” and “clarity” may refer to an optical phenomenon associated with the transmission of light through a material, and may be attributed, for example, to the refraction of light within the material, e.g., due to secondary phases or porosity and/or the reflection of light from one or more surfaces of the material. As will be appreciated by those skilled in the art, haze may be associated with an amount of light that is subject to wide angle scattering (i.e., at an angle greater than 2.5° from normal) and a corresponding loss of transmissive contrast, whereas clarity may relate to an amount of light that is subject to narrow angle scattering (i.e., at an angle less than 2.5° from normal) and an attendant loss of optical sharpness or “see through quality.”

After extrusion or casting, a polyethylene film can be oriented either uniaxially or biaxially as a single layer or multilayer to form a mechanically anisotropic and optically clear film that may exhibit anisotropy also in its thermal conductivity. An anisotropic polymer thin film may be formed using a thin film orientation system configured to heat and stretch a polymer thin film in at least one in-plane direction in one or more distinct regions thereof. In some embodiments, a thin film orientation system may be configured to stretch a polymer thin film, i.e., a crystallizable polymer thin film, along only one in-plane direction. For instance, a thin film orientation system may be configured to apply an in-plane stress to a polymer thin film along the x-direction while allowing the thin film to relax along an orthogonal in-plane direction (e.g., along the y-direction). As used herein, the relaxation of a polymer thin film may, in certain examples, accompany the absence of an applied stress along a relaxation direction.

According to some embodiments, within an example orientation system, a polymer thin film may be heated and stretched transversely to a direction of film travel through the system. In such embodiments, a polymer thin film may be held along opposing edges by plural movable clips slidably disposed along a diverging track system such that the polymer thin film is stretched in a transverse direction (TD) as it moves along a machine direction (MD) through heating and deformation zones of the thin film orientation system. In some embodiments, the stretching rate in the transverse direction and the relaxation rate in the machine direction may be independently and locally controlled. In certain embodiments, large scale production may be enabled, for example, using a roll-to-roll manufacturing platform.

In certain aspects, the tensile stress may be applied uniformly or non-uniformly along a lengthwise or widthwise dimension of the polymer thin film. Heating of the polymer thin film may accompany the application of the tensile stress. For instance, a semi-crystalline polymer thin film may be heated to a temperature greater than room temperature (˜23° C.) to facilitate deformation of the thin film and the formation and realignment of crystals and/or polymer chains therein.

The temperature of the polymer thin film may be maintained at a desired value or within a desired range before, during and/or after an act of stretching, i.e., within a pre-heating zone or a deformation zone located downstream of the pre-heating zone, in order to improve the deformability of the polymer thin film relative to an un-heated polymer thin film. The temperature of the polymer thin film within a deformation zone may be less than, equal to, or greater than the temperature of the polymer thin film within a pre-heating zone.

In some embodiments, the polymer thin film may be heated to a constant temperature throughout an act of stretching. In some embodiments, a region of the polymer thin film may be heated to different temperatures, i.e., during and/or subsequent to the application of a tensile stress. In some embodiments, different regions of the polymer thin film may be heated to different temperatures. In certain embodiments, the strain realized in response to the applied tensile stress may be at least approximately 20%, e.g., approximately 20%, approximately 50%, approximately 100%, approximately 200%, approximately 400%, approximately 500%, approximately 1000%, approximately 2000%, approximately 3000%, or approximately 4000% or more, including ranges between any of the foregoing values.

The crystalline content within the polymer thin film may increase during an act of stretching. In some embodiments, stretching may alter the orientation of crystals within a polymer thin film without substantially changing the crystalline content.

In some embodiments, a protective layer may be formed over one or both major surfaces of a polymer thin film. The protective layer(s) may include an organic or an inorganic material, and may shield the polymer thin film against surface damage or debris, such as scratches or dust. The protective layer(s), if provided, may be removed prior to one or more acts of stretching, or the protective layer(s) may be removed following stretching. In various examples, the removable protective layer(s) may have a 90° peel strength of at least approximately 10 g/cm width (e.g., 10, 20, 50, 100, 200, 500, 1000 g/cm width or greater).

Following the act(s) of stretching, one or more thin film properties may be refined through hot pressing or hot calendaring. Uniaxial hot pressing, for example, may be performed in a rigid die with loading applied along a common axis. Some pressing systems may include a graphite die, which may be enclosed in a protective atmosphere or vacuum chamber. During hot pressing, temperature and pressure may be applied simultaneously to the stretched polymer thin film. Heating may be achieved using induction coils that surround the graphite die, and pressure may be applied hydraulically. Hot calendaring is a process of compressing a thin film during production by passing a polymer thin film between one or more pairs of heated rollers.

In some embodiments, a stretched polymer thin film may be pressed or calendared to at least approximately 50% of its initial thickness (e.g., 50%, 60%, 70%, or 80% of its initial thickness, including ranges between any of the foregoing values) under an applied pressure of at least approximately 2 MPa (e.g., 2, 3, 4, 5, or 10 MPa, including ranges between any of the foregoing values) and at a temperature of less than approximately 140° C. (e.g., 120° C., 125° C., 130° C., or 135° C., including ranges between any of the foregoing values).

A pressed or calendared polymer thin film may have a thickness of less than approximately 500 micrometers, e.g., less than 400 micrometers, less than 300 micrometers, or less than 200 micrometers. According to some embodiments, following hot pressing or hot calendaring, a polymer thin film may be stretched further using one or more additional stretching steps. In a post-hot pressing or post-hot calendaring stretching step, a polymer thin film may be stretched to a draw ratio of approximately 5 or greater (e.g., 5, 10, 20, 40, 60, 80, 100, 120, or 140, including ranges between any of the foregoing values).

Hot pressing or hot calendaring may increase transmissivity and/or thermal conductivity of a polymer thin film. According to some embodiments, the applied pressure may collapse voids within the polymer thin film, thus decreasing the overall void volume and increasing the density of the polymer matrix.

Following deformation of the polymer thin film, the heating may be maintained for a predetermined amount of time, followed by cooling of the polymer thin film. The act of cooling may include allowing the polymer thin film to cool naturally, at a set cooling rate, or by quenching, such as by purging with a low temperature gas, which may thermally stabilize the polymer thin film.

Following deformation, the crystals or chains may be at least partially aligned with the direction of the applied tensile stress. As such, a polymer thin film or multilayer may exhibit a high degree of optical clarity and mechanical anisotropy, including one or any combination of: transmissivity within or across the visible spectrum (380-750 nm) of at least approximately 85% (e.g., 85, 90, 95, 97, or 99%, including ranges between any of the foregoing values), bulk haze of less than approximately 5% (e.g., 0, 0.5, 1, 2, 3, 4, or 5%, including ranges between any of the foregoing values), RF transparency of at least approximately 85% (e.g., 85, 90, 95, 97, or 99%, including ranges between any of the foregoing values), specific resistivity of at least approximately 10¹⁰ ohm/cm (e.g., 10¹⁰, 10¹², or 10¹⁵ ohm/cm, including ranges between any of the foregoing values), a dielectric constant of less than approximately 3.5 (e.g., 3, 2.5, 2.2, or 2, including ranges between any of the foregoing values), a loss tangent of less than approximately 0.01 (e.g., 0.005, 0.002, 0.001, or 0.0005, including ranges between any of the foregoing values), an elastic modulus of at least approximately 20 GPa (e.g., 20, 30, 40, 50, 60, 70, 80, 90, or 100 GPa, including ranges between any of the foregoing values), tensile strength of at least approximately 0.5 GPa (e.g., 0.5, 1, or 1.5 GPa, including ranges between any of the foregoing values), thermal conductivity along at least one direction of at least approximately 5 W/mK (e.g., 5, 10, 20, 30, 40, 50, 60, 70, or 80 W/mK, including ranges between any of the foregoing values), void volume of less than approximately 5% (e.g., 0, 1, 2, 3, 4, or 5%, including ranges between any of the foregoing values) and an average void size of less than approximately 100 nm (e.g., 10, 20, 50, or 100 nm, including ranges between any of the foregoing values). In some embodiments, the modulus of a polymer thin film may be invariant or substantially invariant as a function of frequency (e.g., over a range of 0.1 to 100 Hz, for example). These and other properties may exhibit an in-plane anisotropy ranging from approximately 2:1 to approximately 100:1 or more, e.g., 2:1, 3:1, 4:1, 5:1, 10:1, 20:1, 50:1, or 100:1.

By way of example, a polymer multilayer may include two or more polymer layers each formed from ultra-drawn ultra-high molecular weight polyethylene, where the polymer multilayer has a total thickness of at least approximately 50 micrometers, and each polymer layer within the polymer multilayer has transparency within the RF spectrum of at least approximately 85%, a specific resistivity of at least approximately 10¹⁰ ohm/cm, a dielectric constant of less than approximately 3.5, a loss tangent of less than approximately 0.01, and a thermal conductivity of at least approximately 5 W/mK.

Polyethylene or other polymer thin films may include fibrous, amorphous, partially crystalline, or wholly crystalline materials. Such materials may also exhibit anisotropy with respect to one or more further characteristics, which may include compressive strength, shear strength, yield strength, stiffness, hardness, toughness, ductility, machinability, thermal expansion, and creep behavior.

In accordance with various embodiments, an anisotropic polyethylene thin film may be formed by applying a desired stress state to a crystallizable polymer thin film. A polymer composition capable of crystallizing may be formed into a single layer using appropriate extrusion and casting operations well known to those skilled in the art. For example, an ethylene-containing composition may be extruded and oriented as a single layer to form a mechanically and thermal conductively anisotropic thin film. According to further embodiments, a crystallizable polymer may be co-extruded with other polymer materials that are either crystallizable, or those that remain amorphous after orientation to form a multilayer structure. In other cases, a multilayer PE thin film may be formed through layer-by-layer lamination of single layer stretched PE films.

Following deformation, the crystals or chains may be at least partially aligned with the direction of the applied tensile stress. As such, a polyethylene thin film may exhibit a high degree of optical clarity and in-plane anisotropy, including an in-plane thermal conductivity of at least approximately 5 W/mK, and an elastic modulus of at least approximately 20 GPa.

In further embodiments, a polyethylene thin film may be incorporated into a multilayer structure, such as the “A” layer in an ABAB multilayer. Further multilayer architectures include AB, ABA, or ABC configurations. Each B layer (and each C layer, if provided) may include a further polymer composition or other material layer. In embodiments where a PE-containing multilayer is configured as a heat dissipative layer, the B (and C) layer(s) may be configured to reflect heat. In example multilayer architectures, adjacent polyethylene layers may be bonded together using an adhesive layer. An adhesive layer may be configured to provide a low thermal contact resistivity and good adhesion between neighboring layers. An adhesive layer may include powdered UHMWPE, a polyethylene thin film, or a polystyrene block copolymer thin film, for example.

In a single layer or multilayer architecture, a polyethylene or other polymer layer may have a thickness ranging from approximately 100 nm to approximately 5 mm, e.g., 100, 200, 500, 1000, 2000, 5000, 10000, 20000, 50000, 100000, 200000, 500000, 1000000, 2000000, or 5000000 nm, including ranges between any of the foregoing values. A total multilayer stack may include two or more such layers.

According to some embodiments, the areal dimensions (i.e., length and width) of a polyethylene or other polymer thin film may independently range from approximately 5 cm to approximately 50 cm or more, e.g., 5, 10, 20, 30, 40, or 50 cm, including ranges between any of the foregoing values. Example anisotropic polymer thin films may have areal dimensions of approximately 5 cm×5 cm, 10 cm×10 cm, 20 cm×20 cm, 50 cm×50 cm, 5 cm×10 cm, 10 cm×20 cm, 10 cm×50 cm, etc.

Aspects of the present disclosure thus relate to polymer laminates that include plural layers of ultra-high molecular weight polyethylene (UHMWPE), although polymer laminates may include alternate polymer materials such as polybenzoxazole. Example polymer multilayers may exhibit improved mechanical, thermal conductivity, and optical properties, and may provide thermal management solutions for wearable devices, including VR/AR/MR systems.

Features from any of the embodiments described herein may be used in combination with one another in accordance with the general principles described herein. These and other embodiments, features, and advantages will be more fully understood upon reading the following detailed description in conjunction with the accompanying drawings and claims.

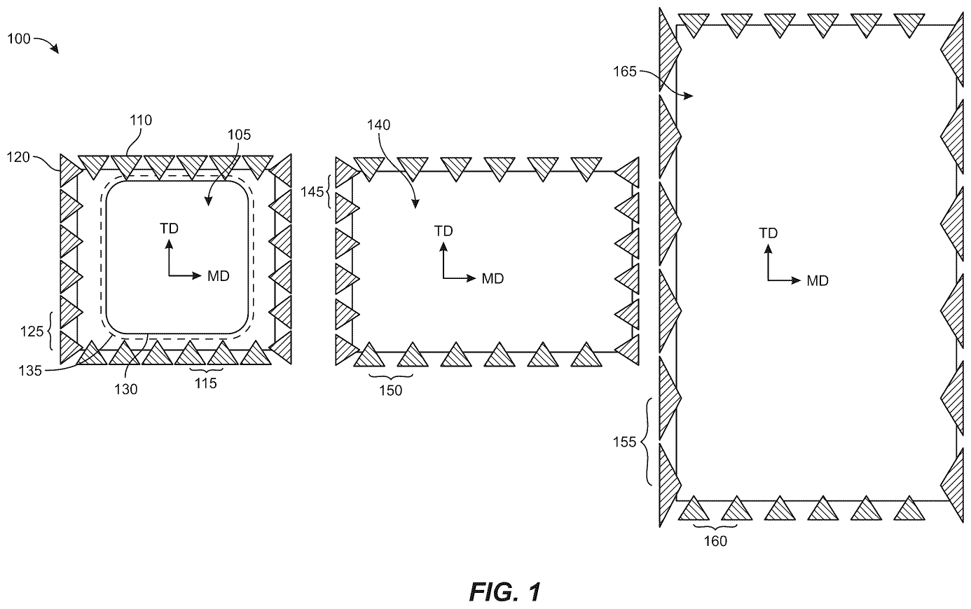

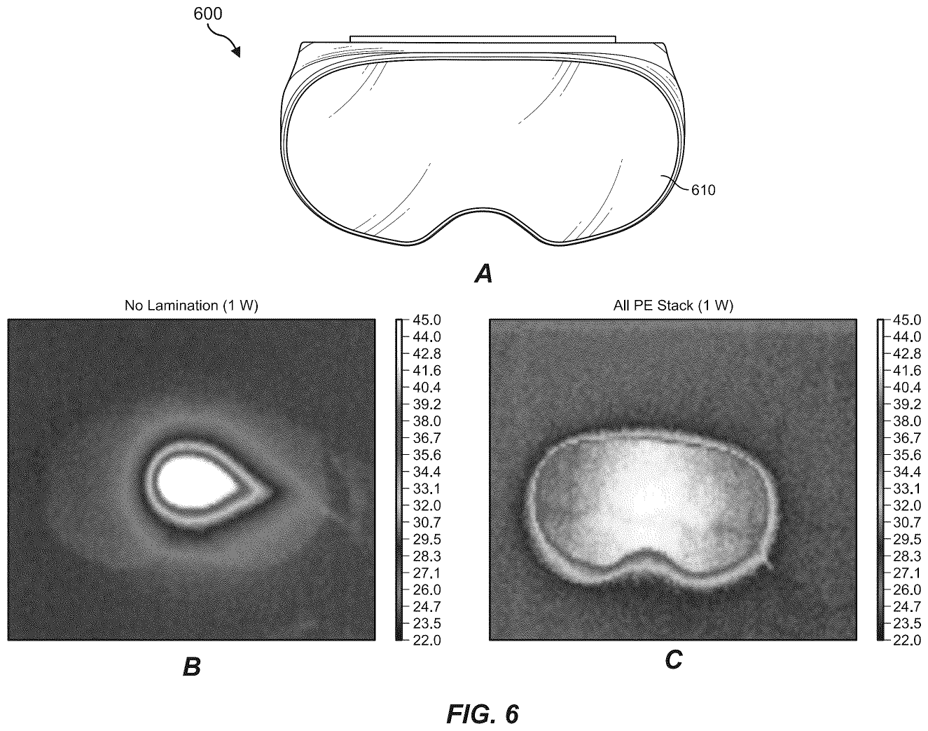

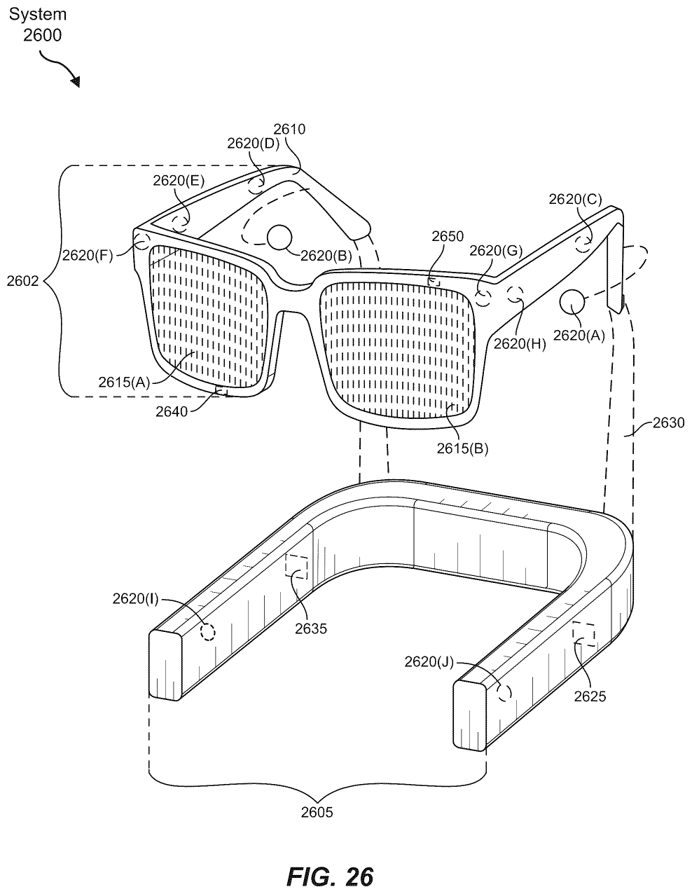

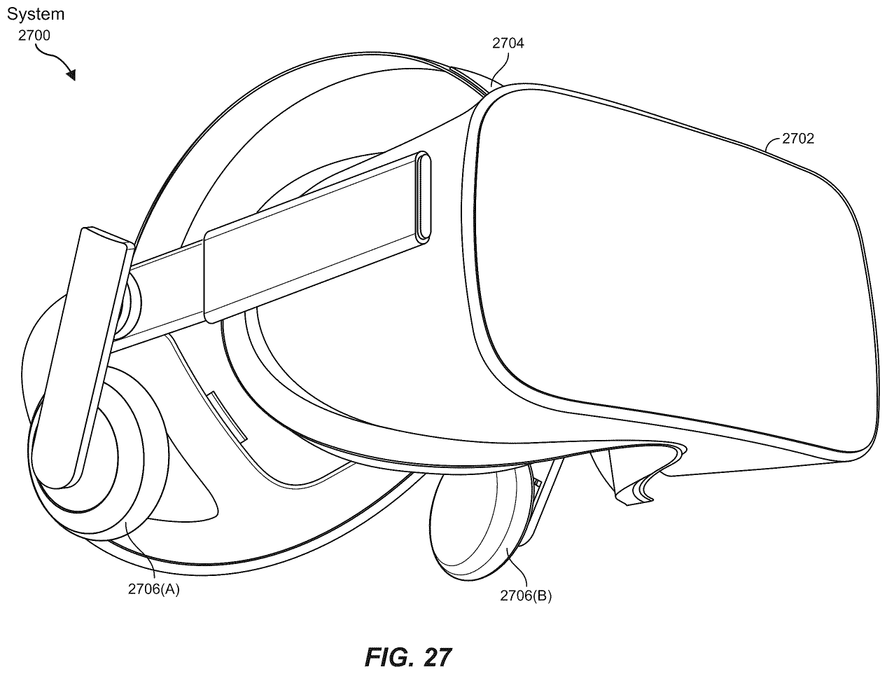

The following will provide, with reference to FIGS. 1-27, a detailed description of ultra-high molecular weight polyethylene multilayers, including their methods of manufacture. The discussion associated with FIGS. 1-5 relates to example polymer thin film stretching paradigms and associated stretching apparatus and thin film architectures. The discussion associated with FIGS. 6-25 relates to the thermal properties of UHMWPE thin films and multilayers. The discussion associated with FIGS. 26 and 27 relates to exemplary virtual reality and augmented reality devices that may include an ultra-high molecular weight polyethylene-containing thin film or multilayer as disclosed herein.

In conjunction with various embodiments, a polymer thin film may be described with reference to three mutually orthogonal axes that are aligned with the machine direction (MD), the transverse direction (TD), and the normal direction (ND) of a thin film orientation system, and which may correspond respectively to the length, width, and thickness dimensions of the polymer thin film. Throughout various embodiments and examples of the instant disclosure, the machine direction may correspond to the x-direction of a polymer thin film, the transverse direction may correspond to the y-direction of the polymer thin film, and the normal direction may correspond to the z-direction of the polymer thin film.

Referring to FIG. 1, shown schematically is an orthogonal consecutive stretching (OSC) system 100 and a corresponding method where a polymer thin film 105 may be first stretched in the machine direction (MD) and then stretched in the transverse direction (TD). In the illustrated embodiment, polymer thin film 105 may be initially secured between opposing clip arrays 110, 120. The inter-clip spacing 115 within clip array 110 and the inter-clip spacing 125 within clip array 120 may be independently controlled. Thus, throughout a stretching process, an inter-clip spacing along different axes of system 100 may decrease, increase, or be held constant. According to various embodiments, stretching of the polymer thin film 105 in the machine direction and stretching of the polymer thin film 105 in the transverse direction may occur simultaneously and/or successively.

By way of example, and referring still to FIG. 1, cast polymer thin film 105 may be stretched in a first stretching step along a first axis, cooled and optionally cut to a desired width, and then stretched in a second stretching step. A temperature of the polymer thin film during the second stretching step may be at least approximately 5° C. greater than a temperature of the polymer thin film during the first stretching step (e.g., approximately 5° C., approximately 10° C., approximately 15° C., or approximately 20° C. greater, including ranges between any of the foregoing values).

During a second stretching step, the polymer thin film may be stretched along the first axis or, as illustrated in FIG. 1, along a second axis perpendicular to the first axis. By way of example, a draw ratio during the first stretching step may be less than approximately 4, e.g., approximately 2, or approximately 3, including ranges between any of the foregoing values. The draw ratio during the second stretching step may be at least approximately 7, e.g., approximately 7, approximately 10, approximately 20, approximately 30, approximately 40, or more, including ranges between any of the foregoing values. In some embodiments, the draw ratio during the first stretching step may be less than the draw ratio during the second stretching step. Following the second stretching step, the polymer thin film may be heated to increase its crystalline content. As used herein, a polymer thin film processed to a draw ratio of at least approximately 4 may be referred to as an ultra-drawn thin film.

Prior to the acts of stretching, a polymer thin film may be pre-aligned, i.e., with respect to the stretch axes of a thin film orientation system. Pre-alignment of the polymer thin film may allow polymer chains within the polymer thin film to form a cross-linked crystal network. This cross-linked crystal network may allow the polymer film to be stretched to higher draw ratios compared to thin films that are stretched only in a single direction and without pre-alignment.

Referring still to FIG. 1, heaters 130, 135 may be respectively located above and below the plane of polymer thin film 105, and may be configured to control a temperature of the polymer thin film during the acts of stretching. Heaters 130, 135 may include hot air blowers, for example. A temperature of a polymer thin film may be constant or substantially constant during one or more acts of stretching. Alternatively, a temperature of a polymer thin film may increase or decrease throughout stretching processes. Example temperatures may be greater than the polymer's glass transition temperature (T_{g}) but less than an onset temperature for melting (Tₘ).

During a first stretching process, an inter-clip spacing 150 within clip array 110 may increase, while an inter-clip spacing 145 within clip array 120 may be fixed. Accordingly, a tensile stress may be applied to the polymer thin film 105 along the machine direction (MD) while the polymer thin film is unstressed along the transverse direction (TD), thus forming a uniaxially stretched polymer thin film 140. During a second and subsequent stretching process, an inter-clip spacing 155 within clip array 120 may increase, while an inter-clip spacing 160 within clip array 110 may be fixed. Thus, a tensile stress may be applied to the polymer thin film 140 along the transverse direction (TD) while the polymer thin film is unstressed along the machine direction (MD), thus forming an OCS processed polymer thin film 165.

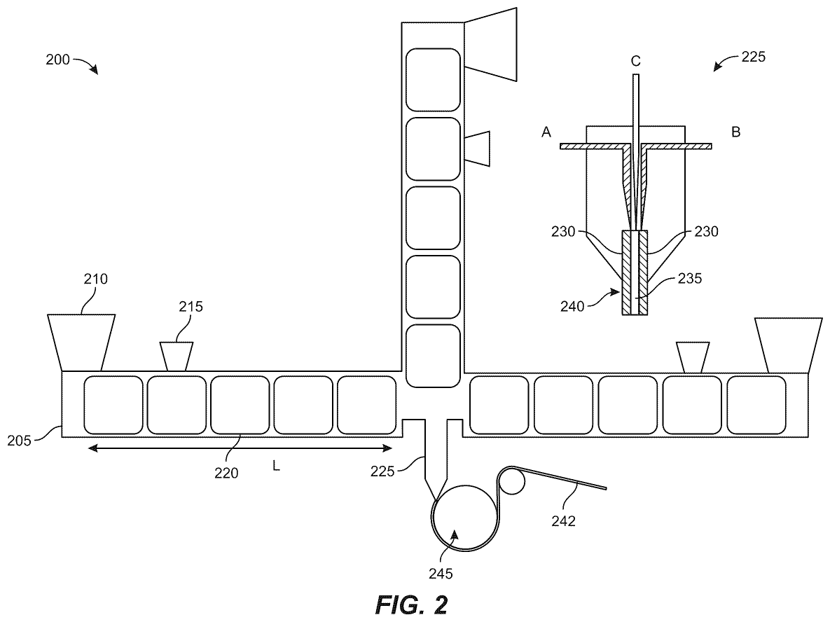

Referring now to FIG. 2, shown schematically is an example extrusion system for forming a cast polymer thin film. An extrusion system 200 may be configured to form a single layer polymer thin film or, as shown in the illustrated embodiment, a multilayer polymer thin film from plural sources. Different sources of feedstock may differ compositionally, for example. Multilayer polymer thin films may include 2 or more layers, where individual layers may be formed simultaneously in situ or aggregated to form a multilayer having, for example, 4, 8, 16, 32, 64, 128, 256, 512, or a greater number of individual layers.

During operation, a resin typically provided in powder or pellet form may be fed into extruder 205 from a hopper 210. One or more optional additives may be blended with the resin within hopper 210 or incorporated using a separate downstream hopper 215. The temperature of extruder 205 along its length (L) may be controlled by heating elements 220. Extruder 205 may include a screw or other element (not shown) for mixing, homogenizing, and driving feedstock from hoppers 210, 215 to an extrusion die 225.

As shown in the inset, extrusion die 225 may include plural inputs A, B, C, that are configured to receive feedstock from plural respective extruders (e.g., extruder 205, etc.). In some embodiments, the temperature of the die 225 may be greater than the melting point of the feedstock. The melted feedstock may be output through die 225 to form a multilayer thin film 240 that may include, for example, a central polymer layer 235 and a pair of outer layers 230 that sandwich the central layer 235. Multilayer thin film 240 may be initially collected on a chilled roller 245 and output as a pre-oriented cast thin film 242. The temperature of the chilled roller 245 may be selected based on the type of additive(s) used in the process. The rotational rate of the chilled roller 245 (i.e., relative to the output rate of the extrusion die 225) may be adjusted to pre-orient multilayer thin film 240.

In some embodiments, the central layer 235 may include ultra-high molecular weight polyethylene (UHMWPE). Each outer layer 230 may include a material having a high surface energy relative to polyethylene (e.g., fluoropolymers such as polyvinylidene fluoride or polyesters such as polyethylene terephthalate) or materials having a low surface energy relative to polyethylene (e.g., polyolefins such as polypropylene).

Prior to an act of stretching, one or both of the outer layers 230 may be removed from the multilayer thin film 240. By way of example, the outer layer(s) 230 may be removed prior to stretching the central layer 235, removed after one stage of the stretching (e.g., removed after stretching along the machine direction), or removed following two stages of stretching (e.g., removed following an OCS process). In some embodiments, the outer layers 230 may be removed from the central layer 235 by peeling. In some embodiments, the outer layers 230 may have a 90° peel strength of at least approximately 10 g/cm width, e.g., 10, 20, 50, 100, 500, or 1000 g/cm width, including ranges between any of the foregoing values.

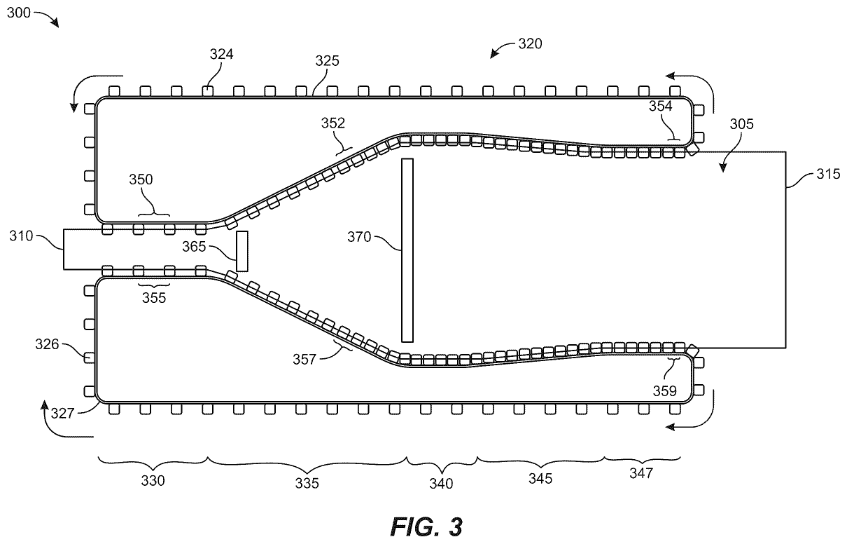

A single stage thin film orientation system for forming an anisotropic polymer thin film is shown schematically in FIG. 3. System 300 may include a thin film input zone 330 for receiving and pre-heating a crystallizable portion 310 of a polymer thin film 305, a thin film output zone 347 for outputting a crystallized and oriented portion 315 of the polymer thin film 305, and a clip array 320 extending between the input zone 330 and the output zone 347 that is configured to grip and guide the polymer thin film 305 through the system 300, i.e., from the input zone 330 to the output zone 347. Clip array 320 may include a plurality of movable first clips 324 that are slidably disposed on a first track 325 and a plurality of movable second clips 326 that are slidably disposed on a second track 327.

During operation, proximate to input zone 330, clips 324, 326 may be affixed to respective edge portions of polymer thin film 305, where adjacent clips located on a given track 325, 327 may be disposed at an inter-clip spacing 350, 355. For simplicity, in the illustrated view, the inter-clip spacing 350 along the first track 325 within input zone 330 may be equivalent or substantially equivalent to the inter-clip spacing 355 along the second track 327 within input zone 330. As will be appreciated, in alternate embodiments, within input zone 330, the inter-clip spacing 350 along the first track 325 may be different than the inter-clip spacing 355 along the second track 327.

In addition to input zone 330 and output zone 347, system 300 may include one or more additional zones 335, 340, 345, etc., where each of: (i) the translation rate of the polymer thin film 305, (ii) the shape of first and second tracks 325, 327, (iii) the spacing between first and second tracks 325, 327, (iv) the inter-clip spacing 350, 352, 354, 355, 357, 359, and (v) the local temperature of the polymer thin film 305, etc. may be independently controlled.

In an example process, as it is guided through system 300 by clips 324, 326, polymer thin film 305 may be heated to a selected temperature within each of zones 330, 335, 340, 345, 347. Fewer or a greater number of thermally controlled zones may be used. As illustrated, within zone 335, first and second tracks 325, 327 may diverge along a transverse direction such that polymer thin film 305 may be stretched in the transverse direction while being heated, for example, to a temperature greater than its glass transition temperature (T_{g}) but less than the onset of melting.

Referring still to FIG. 3, within zone 335 the spacing 352 between adjacent first clips 324 on first track 325 and the spacing 357 between adjacent second clips 326 on second track 327 may decrease relative to the inter-clip spacing 350, 355 within input zone 330. In certain embodiments, the decrease in clip spacing 352, 357 from the initial spacing 350, 355 may scale approximately as the square root of the transverse stretch ratio. The actual ratio may depend on the Poisson's ratio of the polymer thin film as well as the requirements for the stretched thin film, including flatness, thickness, etc. Accordingly, in some embodiments, the in-plane axis of the polymer thin films that is perpendicular to the stretch direction may relax by an amount equal to the square root of the stretch ratio in the stretch direction. By decreasing the clip spacings 352, 357 relative to inter-clip spacing 350, 355 the polymer thin film may be allowed to relax along the machine direction while being stretched along the transverse direction.

A temperature of the polymer thin film may be controlled within each heating zone. Withing stretching zone 335, for example, a temperature of the polymer thin film 305 may be constant or independently controlled within sub-zones 365, 370, for example. In some embodiments, the temperature of the polymer thin film 305 may be decreased as the stretched polymer thin film 305 enters zone 340. Rapidly decreasing the temperature (i.e., thermal quenching) following the act of stretching within zone 335 may enhance the conformability of the polymer thin film 305. In some embodiments, the polymer thin film 305 may be thermally stabilized, where the temperature of the polymer thin film 305 may be controlled within each of the post-stretch zones 340, 345, 347. A temperature of the polymer thin film may be controlled by forced thermal convection or by radiation, for example, IR radiation, or a combination thereof.

Downstream of stretching zone 335, according to some embodiments, a transverse distance between first track 325 and second track 327 may remain constant or, as illustrated, initially decrease (e.g., within zone 340 and zone 345) prior to assuming a constant separation distance (e.g., within output zone 347). In a related vein, the inter-clip spacing downstream of stretching zone 335 may increase or decrease relative to inter-clip spacing 352 along first track 325 and inter-clip spacing 357 along second track 327. For example, inter-clip spacing 355 along first track 325 within output zone 347 may be less than inter-clip spacing 352 within stretching zone 335, and inter-clip spacing 359 along second track 327 within output zone 347 may be less than inter-clip spacing 357 within stretching zone 335. According to some embodiments, the spacing between the clips may be controlled by modifying the local velocity of the clips on a linear stepper motor line, or by using an attachment and variable clip spacing mechanism connecting the clips to the corresponding track.

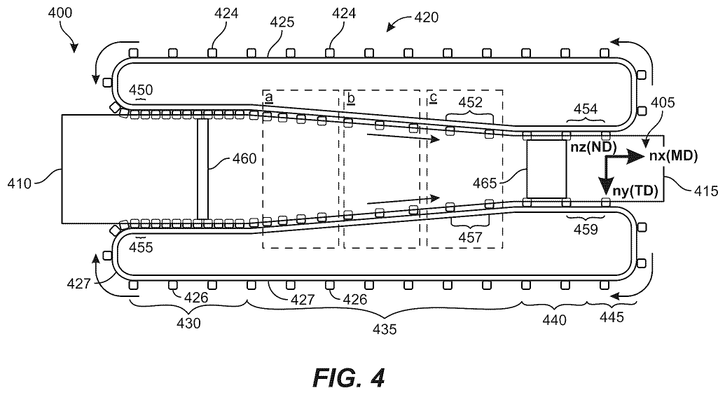

To facilitate cross-stretch relaxation while stretching in the TD direction, the inter-clip spacings 352, 357 withing stretching zone 335 may be decreased by at least approximately 20% (e.g., 20%, 30%, 40%, or 50% or more) relative to respective inter-clip spacings 350, 355 within input zone 330. The relaxation profile may be constant or variable, i.e., as a function of position, across stretching zone 335. According to some embodiments, a maximum TD draw ratio within stretching zone 335 be at least approximately 2 and less than approximately 4. The stretched and oriented polymer thin film 315 may be removed from system 300 and stretched in a further stretching step, such as via length orientation with relaxation as shown in FIG. 4.

Referring to FIG. 4, shown is a further example system for forming an anisotropic polymer thin film. Thin film orientation system 400 may include a thin film input zone 430 for receiving and pre-heating a crystalline or crystallizable portion 410 of a polymer thin film 405, a thin film output zone 445 for outputting an at least partially crystallized and oriented portion 415 of the polymer thin film 405, and a clip array 420 extending between the input zone 430 and the output zone 445 that is configured to grip and guide the polymer thin film 405 through the system 400. As in the previous embodiment, clip array 420 may include a plurality of first clips 424 that are slidably disposed on a first track 425 and a plurality of second clips 426 that are slidably disposed on a second track 427. In certain embodiments, crystalline or crystallizable portion 410 may correspond to stretched and oriented polymer thin film 315.

In an example process, proximate to input zone 430, first and second clips 424, 426 may be affixed to edge portions of polymer thin film 405, where adjacent clips located on a given track 425, 427 may be disposed at an initial inter-clip spacing 450, 455, which may be substantially constant or variable along both tracks within input zone 430. Within input zone 430 a distance along the transverse direction between first track 425 and second track 427 may be constant or substantially constant.

System 400 may additionally include one or more zones 435, 440, etc. The dynamics of system 400 allow independent control over: (i) the translation rate of the polymer thin film 405, (ii) the shape of first and second tracks 425, 427, (iii) the spacing between first and second tracks 425, 427 along the transverse direction, (iv) the inter-clip spacing 450, 455 within input zone 430 as well as downstream of the input zone (e.g., inter-clip spacings 452, 454, 457, 459), and (v) the local temperature of the polymer thin film, etc.

In an example process, as it is guided through system 400 by clips 424, 426, polymer thin film 405 may be heated to a selected temperature within each of zones 430, 435, 440, 445. A temperature greater than the glass transition temperature of a component of the polymer thin film 405 may be used during deformation (i.e., within zone 435), whereas a lesser temperature, an equivalent temperature, or a greater temperature may be used within each of one or more downstream zones.

As in the previous embodiment, the temperature of the polymer thin film 405 within stretching zone 435 may be locally controlled. According to some embodiments, the temperature of the polymer thin film 405 may be maintained at a constant or substantially constant value during the act of stretching. According to further embodiments, the temperature of the polymer thin film 405 may be incrementally increased within stretching zone 435. That is, the temperature of the polymer thin film 405 may be increased within stretching zone 435 as it advances along the machine direction. By way of example, the temperature of the polymer thin film 405 within stretching zone 435 may be locally controlled within each of heating zones a, b, and c.

The temperature profile may be continuous, discontinuous, or combinations thereof. As illustrated in FIG. 4, heating zones a, b, and c may extend across the width of the polymer thin film 405, and the temperature within each zone may be independently controlled according to the relationship T_{g}<Tₐ<T_{b}<T_{c}<Tₘ. A temperature difference between neighboring heating zones may be less than approximately 20° C., e.g., less than approximately 10° C., or less than approximately 5° C.

Referring still to FIG. 4, within zone 435 the spacing 452 between adjacent first clips 424 on first track 425 and the spacing 457 between adjacent second clips 426 on second track 427 may increase relative to respective inter-clip spacings 450, 455 within input zone 430, which may apply an in-plane tensile stress to the polymer thin film 405 and stretch the polymer thin film along the machine direction. Moreover, the extent of inter-clip spacing on one or both tracks 425, 427 within deformation zone 435 may be constant or variable and, for example, increase as a function of position along the machine direction.

Within stretching zone 435, the inner-clip spacings 452, 457 may increase linearly such that the primary mode of deformation may be at constant velocity. For example, a strain rate of the polymer thin film may decrease along the machine direction. In further embodiments, the polymer thin film 405 may be stretched at a constant strain-rate where the inter-clip spacing may increase exponentially.

In certain examples, a progressively decreasing strain rate may be implemented with thin film orientation system 400 to generate a high refractive index polymer thin film. For instance, within stretching zone 435 an inter-clip spacing may be configured such that a distance between each successive pair of clips 424, 426 increases along the machine direction. The inter-clip spacing between each successive pair of clips may be independently controlled to achieve a desired strain rate along the machine direction.

In response to the tensile stress applied along the machine direction, system 400 is configured to inhibit the generation of stresses and an attendant realignment of crystals along the machine direction. As illustrated, within zone 435, first and second tracks 425, 427 may converge along a transverse direction such that polymer thin film 405 may relax in the transverse direction while being stretched in the machine direction. Using a single stretching step or multiple stretching steps, polymer thin film 405 may be stretched by a factor of at least approximately 4 (e.g., 4, 5, 6, 7, 8, 9, 10, 20, 40, 100, or more, including ranges between any of the foregoing values).

Within stretching zone 435, an angle of inclination of first and second tracks 425, 427 (i.e., with respect to the machine direction) may be constant or variable. In particular examples, the inclination angle within stretching zone 435 may decrease along the machine direction. That is, according to certain embodiments, the inclination angle within heating zone a may be greater than the inclination angle within heating zone b, and the inclination angle within heating zone b may be greater than the inclination angle within heating zone c. Such a configuration may be used to provide a progressive decrease in the relaxation rate (along the transverse direction) within the stretching zone 435 as the polymer thin film advances through system 400.

In some embodiments, the temperature of the polymer thin film 405 may be decreased as the stretched polymer thin film 405 exits zone 435. In some embodiments, the polymer thin film 405 may be thermally stabilized, where the temperature of the polymer thin film 405 may be controlled within each of the post-deformation zones 440, 445. A temperature of the polymer thin film may be controlled by forced thermal convection or by radiation, for example, IR radiation, or a combination thereof.

Downstream of deformation zone 435, the inter-clip spacing may increase or remain substantially constant relative to inter-clip spacing 452 along first track 425 and inter-clip spacing 457 along second track 427. For example, inter-clip spacing 455 along first track 425 within output zone 445 may be substantially equal to the inter-clip spacing 452 as the clips exit zone 435, and inter-clip spacing 459 along second track 427 within output zone 445 may be substantially equal to the inter-clip spacing 457 as the clips exit zone 435. Following the act of stretching, polymer thin film 405 may be annealed, for example, within one or more downstream zones 440, 445.

The strain impact of the thin film orientation system 400 is shown schematically by unit segments 460, 465, which respectively illustrate pre- and post-deformation dimensions for a selected area of polymer thin film 405. In the illustrated embodiment, polymer thin film 405 has a pre-stretch width (e.g., along the transverse direction) and a pre-stretch length (e.g., along the machine direction). As will be appreciated, a post-stretch width may be less than the pre-stretch width and a post-stretch length may be greater than the pre-stretch length.

In some embodiments, a roll-to-roll system may be integrated with a thin film orientation system, such as thin film orientation system 300 or thin film orientation system 400, to manipulate a polymer thin film.

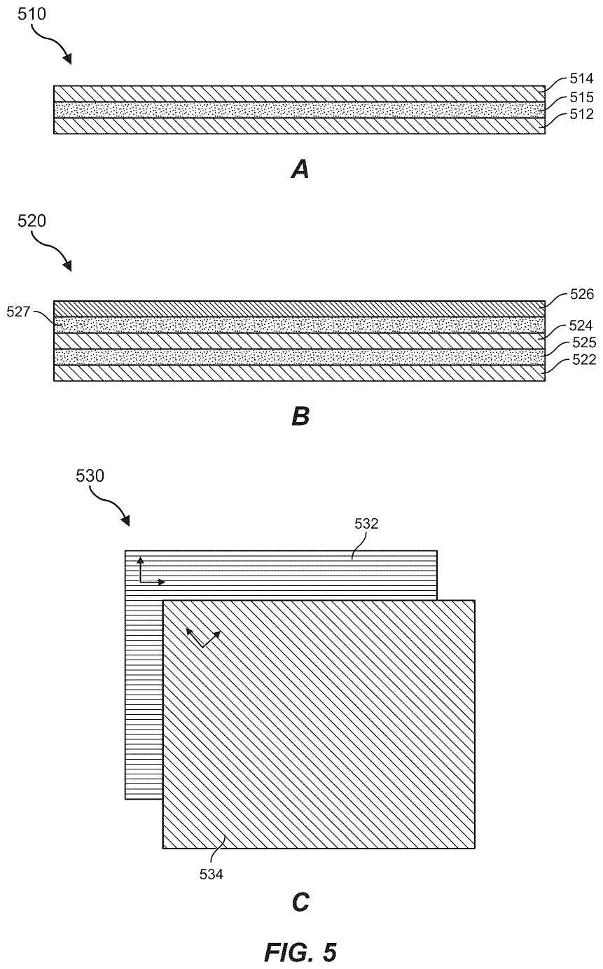

Referring to FIG. 5, shown are cross-sectional views and a top-down plan view of example ultra-high molecular weight polyethylene (UHMWPE)-containing multilayer thin films. As shown in FIG. 5A, multilayer thin film 510 includes first and second polymer layers 512, 514, and an intervening adhesive layer 515. As shown in FIG. 5B, multilayer thin film 520 includes first, second, and third polymer layers 522, 524, 526, and associated intervening adhesive layers 525, 527. In certain embodiments, polymer layer 526 may include a highly emissive (>95%) polymer layer, and may be configured to dispel heat from the multilayer thin film 520 via radiation.

Referring to FIG. 5C, example multilayer thin film 530 includes first and second polymer layers 532, 534. Polymer layers 532, 534 may be drawn layers and, as illustrated schematically, may be mutually misoriented by an in-plane angle of 45°. With such a configuration, one or more in-plane properties, such as thermal conductivity, may be arranged to provide a net in-plane thermal conductivity effective to direct heat flow within the multilayer 530 along a desired in-plane direction, e.g., away from thermally-sensitive regions of a device including regions that are contacted by a user. In the illustrated example of FIG. 5C, adhesive layer(s) are omitted so as to not obscure the illustrated embodiment.

In accordance with particular examples, an ultra-drawn ultra-high molecular weight polyethylene (UHMWPE) multilayer may be incorporated into a VR headset. In example headsets, one or more cameras, projectors, and the like may be located in close proximity to the front cover. As will be appreciated, effective thermal management may allow comfortable and compliant operation of the headset within a specified temperature range.

In some embodiments, a cross-ply UHMWPE multilayer may define the headset front cover itself or, in further examples, may be disposed over the front cover's internal surface. In some examples, the headset may further include one or more thermal routers located between associated power consuming components (e.g., camera, projector, etc.) and the polymer multilayer. Thermal routers may include a graphite or copper sheet, for example. The UHMWPE multilayer may be configured to distribute heat over the front cover's relatively large surface area and accordingly provide an efficient thermal management solution.

Referring to FIG. 6A, shown is a VR headset 600 having a front cover 610. Front cover 610 may provide a large cooling surface using external natural convective and radiative heat transfer modes to disperse heat generated within the headset. A UHMWPE multilayer may be configured to distribute heat over the front cover. In an example evaluation, and with reference initially to FIG. 6B, a condensed thermal profile is shown for a headset where an UHMWPE multilayer is omitted. In FIG. 6B, heat loss is limited and a hot spot is generated proximate to a central region of the headset's front cover. Turning to FIG. 6C, effective heat distribution and dissipation may be achieved by forming an UHMWPE multilayer over an inner surface of the front cover.

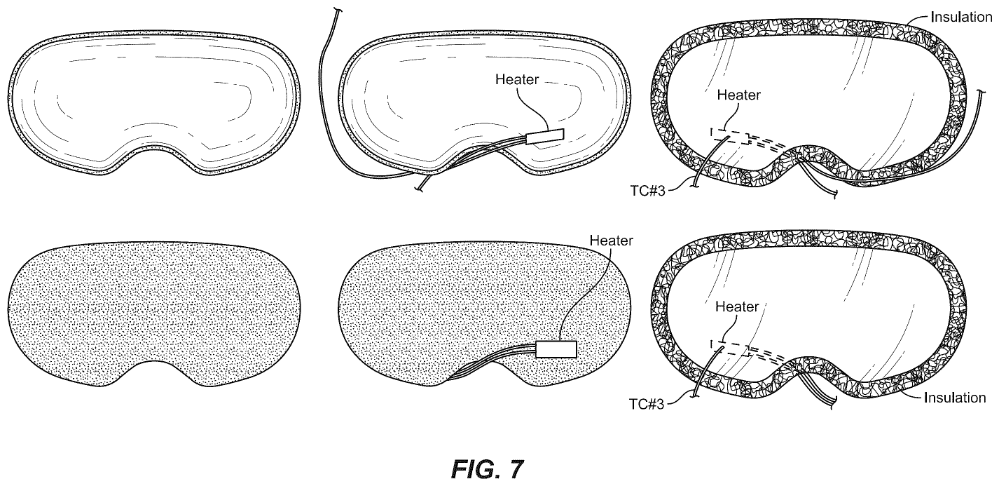

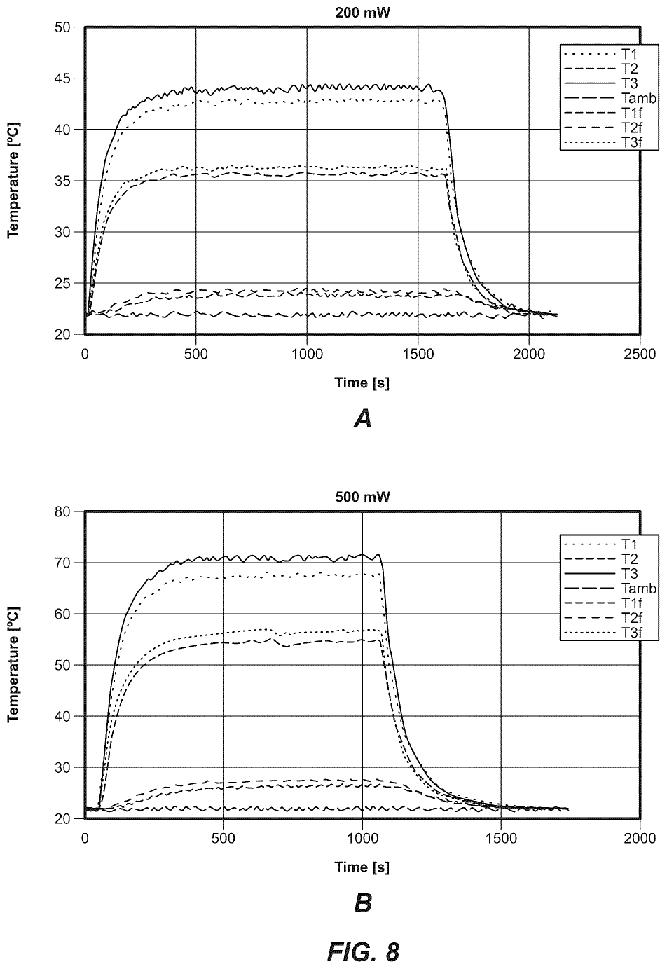

In a further evaluation, a heat source and a plurality of thermocouples are mounted on opposing surfaces of the front cover of a VR headset, as shown in FIG. 7. Referring to FIG. 8, shown are plots of temperature versus time for 200 mW (FIG. 8A) and 500 mW (FIG. 8B) heat sources. The data include the measured temperature at each thermocouple both without an UHMWPE multilayer (solid lines) and with an UHMWPE multilayer (dashed lines).

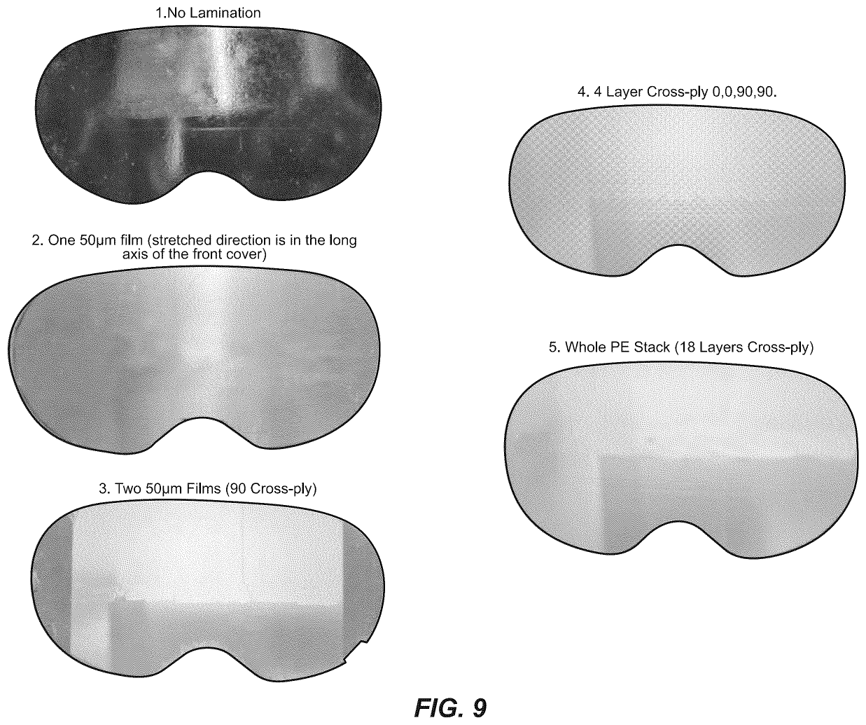

Optical micrographs of a VR headset showing the setup for a still further evaluation are shown in FIGS. 9 and 10. In FIG. 9, the images show a VR headset including: (1) no UHMWPE multilayer, (2) a single 50 micrometer thick layer of UHMWPE disposed over an inner surface of the headset's front cover, (3) a 90° cross-ply UHMWPE bilayer disposed over the front cover's inner surface, (4) a 90° cross-ply UHMWPE multilayer disposed over the front cover's inner surface, and (5) an 18 layer cross-ply UHMWPE multilayer disposed over the front cover's inner surface.

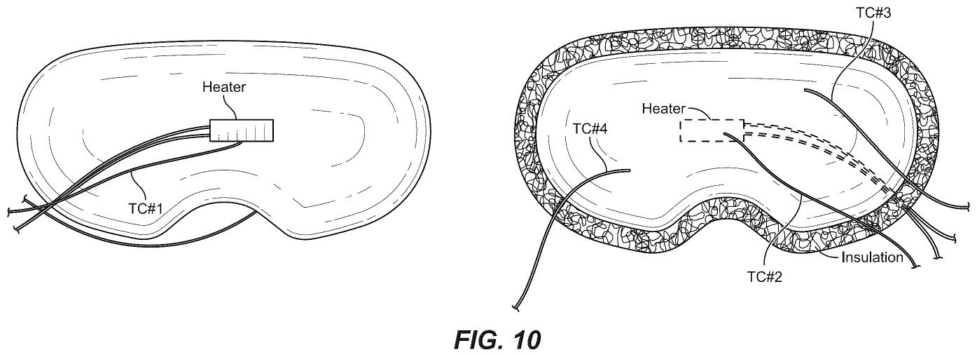

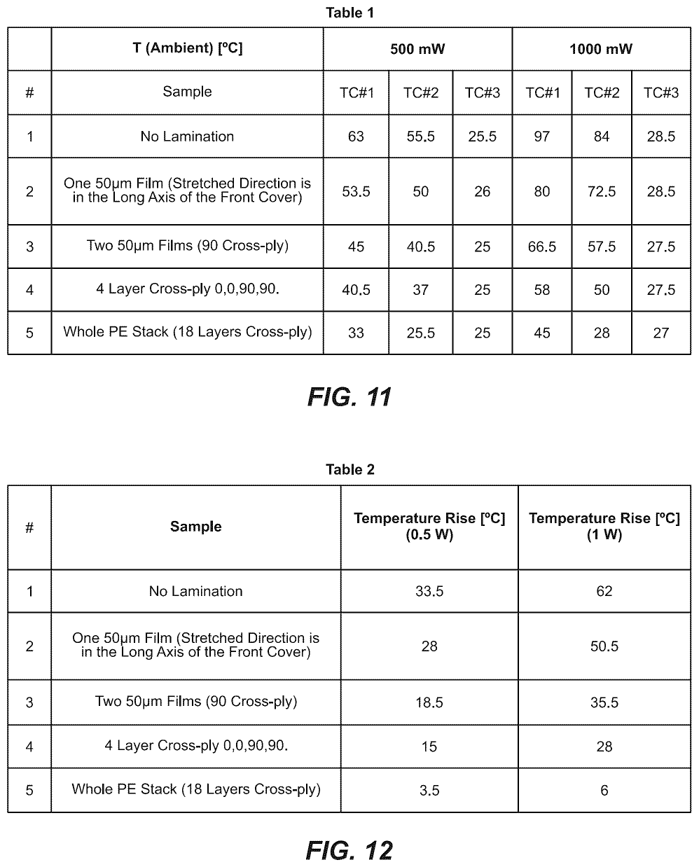

As shown in FIG. 10, a heat source and several thermocouples are attached to the front cover's inner and outer surfaces, and temperatures were measured for input powers of 500 mW and 1000 mW. Referring to FIG. 11 and FIG. 12, thermal data for the evaluation setup shown in FIGS. 9 and 10 are summarized in Tables 1 and 2.

According to some embodiments, a polymer thin film may be configured as a matted layer (i.e., fabric layer) that includes a woven, knit or otherwise assembled plurality of high thermal conductivity fibers. A woven or knit configuration of fibers may include a plain weave, unidirectional weave, biaxial weave, harness strain weave, twill weave, etc. Suitable fibers may have a thermal conductivity along at least one direction of at least approximately 5 W/mK, e.g., 5, 10, 20, 30, 40, 50, or 100 W/mK, including ranges between any of the foregoing values. Example fibers may include polyethylene (e.g., UHMWPE), polybenzoxazole, pitch carbon fiber, Kevlar®, and the like.

In some examples, a matted fiber layer may be impregnated with a second phase, such as a thermoplastic or epoxy resin. In some embodiments, a fiber/epoxy composite may be cured using electromagnetic radiation (e.g., UV light), heat, or a combination thereof. The secondary phase may have a transmissivity within or across the visible spectrum of at least approximately 40%, e.g., 40, 50, 60, 70, 80, or 90%, including ranges between any of the foregoing values.

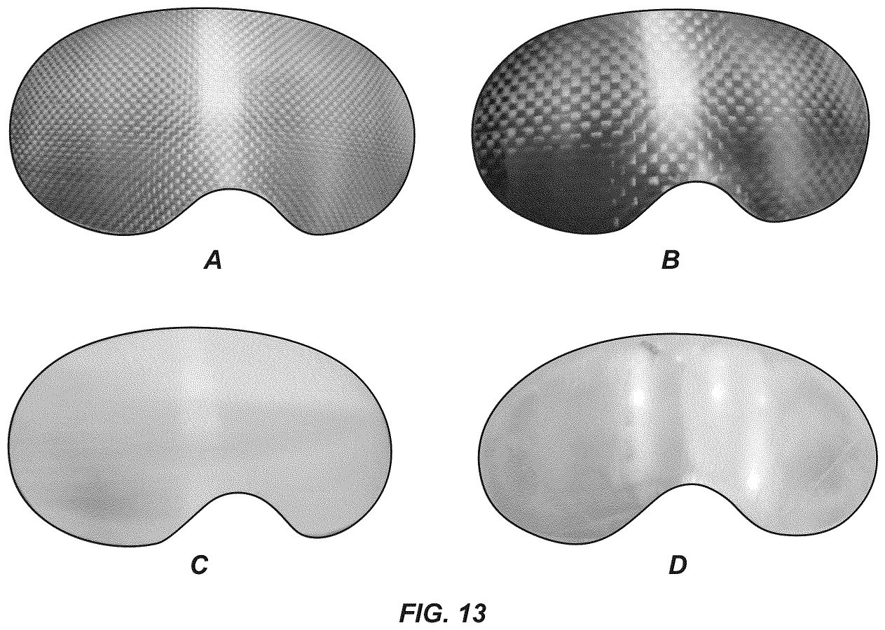

Turning to FIG. 13, a series of optical micrographs are shown for VR headsets having disposed over their respective inner (concave) surfaces a 0.8 micrometer thick layer of (A) a polybenzoxazole (PBO) composite, (B) a pitch carbon fiber (PCF) composite, (C) a polyethylene fiber composite, and (D) a multilayer of consolidated ultra-drawn ultra-high molecular weight polyethylene. In FIGS. 13A and 13B, the composite structures include the listed material dispersed throughout a resinous matrix (30%) of polycarbonate. In FIG. 13C, the polyethylene fibers are dispersed throughout a matrix of a heat curable epoxy having a curing temperature of less than approximately 110° C. In FIG. 13D, the resinous matrix is omitted and a thin layer (10 micrometers) of polyethylene is used as a binder between adjacent UHMWPE layers.

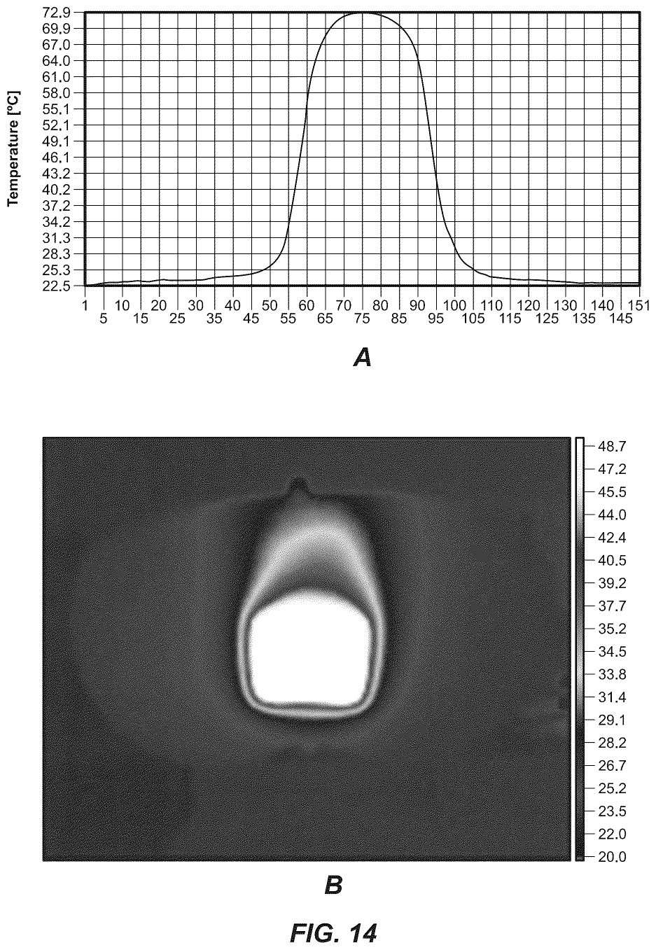

Thermal profile data for a thin layer (0.8 mm) of polycarbonate (thermal conductivity=0.3 W/mK) exposed to a flexible backside resistive heater with an output power of 1.5 W are shown in FIG. 14. Referring to FIG. 14A, profile data show a maximum surface temperature of approximately 73° C. Referring to FIG. 14B, infrared imaging of the headset front cover shows the generation of a hotspot proximate to a central region of the headset with only approximately 16% of the cover's surface area contributing to thermal dissipation with ΔT (T_{surface}−T_{ambient})>3° C.

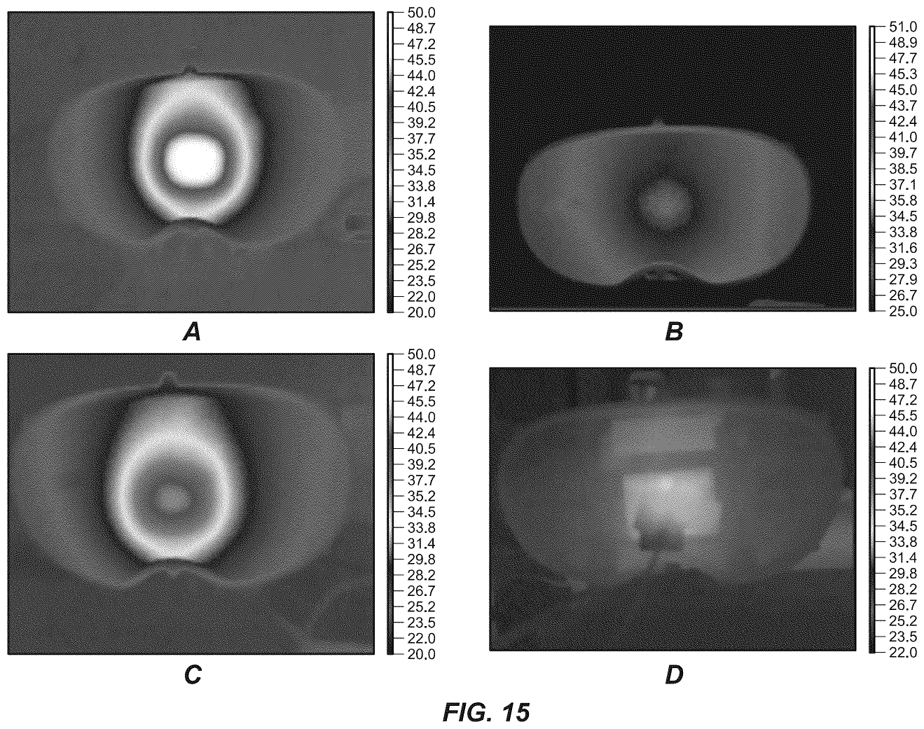

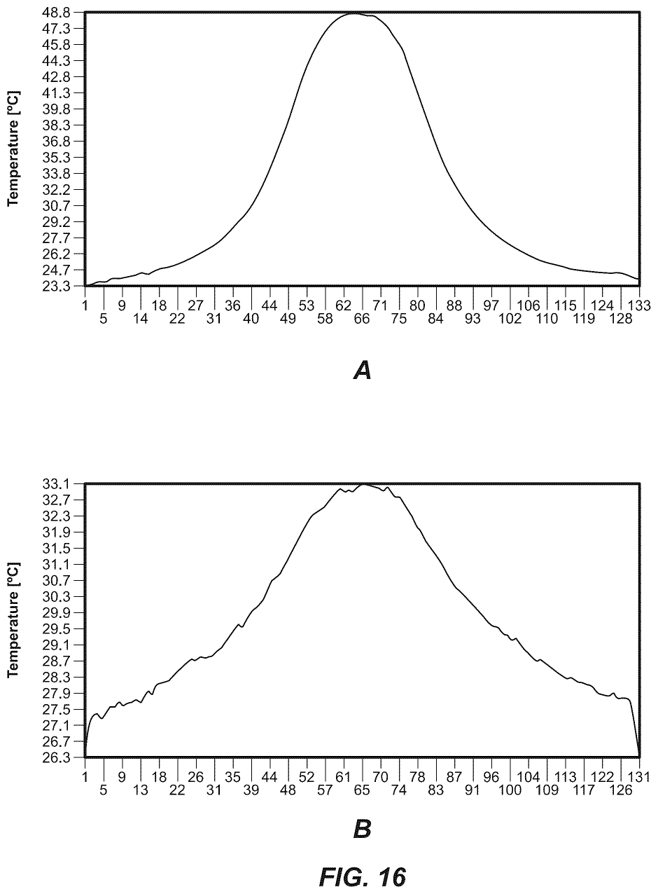

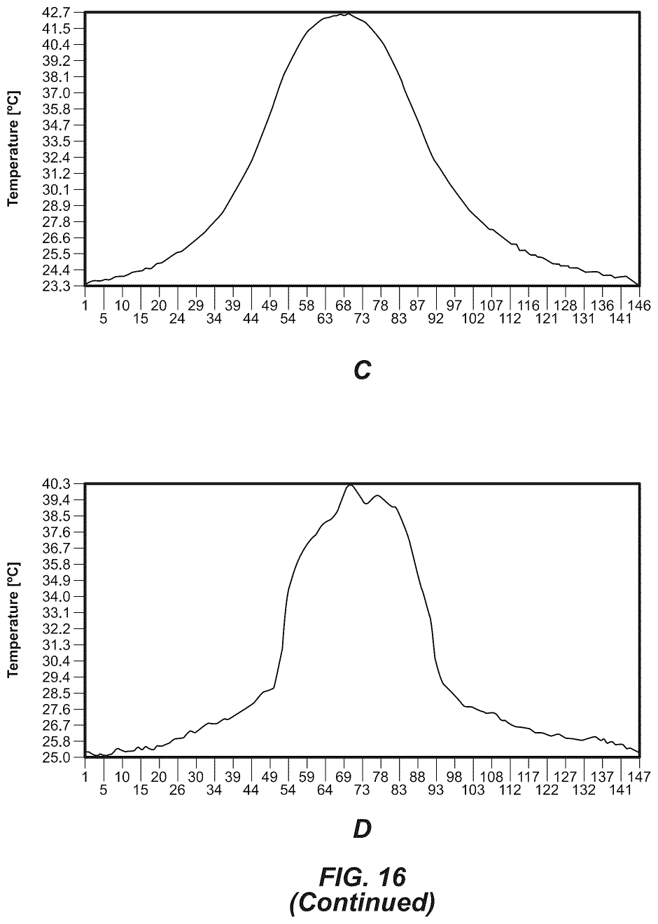

Infrared images of the front cover geometry for the example co-integrated VR headsets of FIG. 13 are shown in FIG. 15. In each assembly, a resistive heater is mounted on the backside of the headset proximate to the center. Relative to polycarbonate alone, the illustrated geometries exhibit improved heat dissipation and a substantial decrease in peak temperature. Corresponding temperature profiles for the images of FIG. 15 are shown in FIG. 16. The data show a significant decrease in maximum surface temperature.

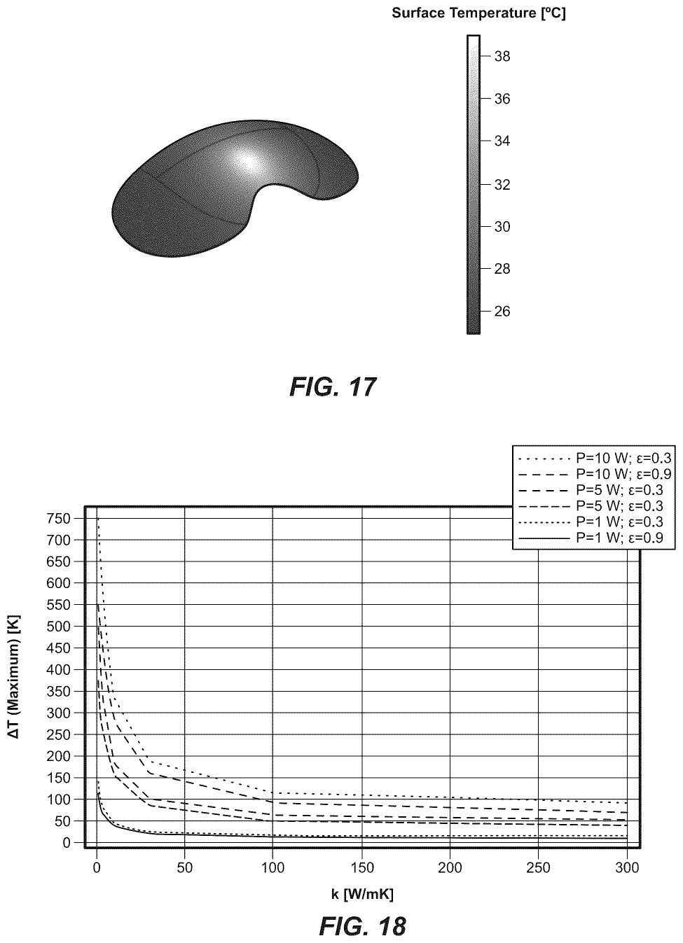

Referring to FIG. 17, shown is the modeled thermal profile across the front cover of a VR headset where the front cover is made from ultra-high molecular weight polyethylene. The model assumes that the thermal conductivity of the polyethylene is isotropic, k=30 W/mK, and that 1.0 W of thermal power is delivered at constant heat flux to the concave side of the headset front cover. In the model, the concave side is insulated and the convex side heat convection coefficient is set to 5 W/m²K, which corresponds to free convection. The emissivity of the surface is set to 0.9.

Turning to FIG. 18, shown is a plot of the maximum temperature difference, ΔTₘₐₓ (=Tₘₐₓ−T_{ambient}), versus thermal conductivity of an UHMWPE substrate for a series of input thermal powers (P) and surface emissivity (ε) values. A minimum thermal conductivity k=30 W/mK is used for all cases to enable significant reduction in the maximum temperature difference. For these results, the power is provided on a small surface ˜3 cm², corresponding to high heat flux.

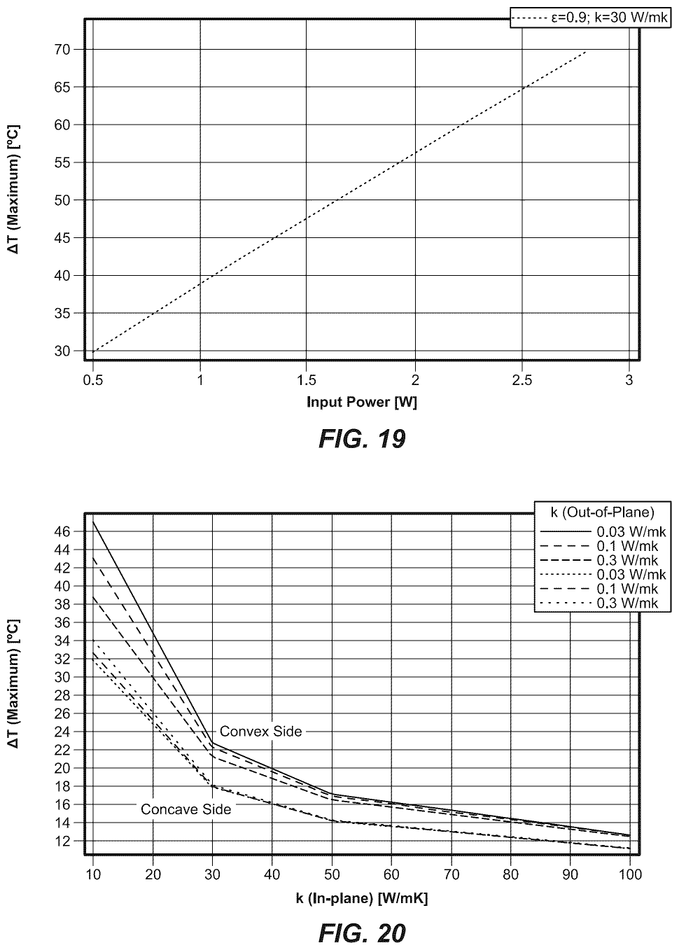

A plot of the maximum temperature difference versus input power at the convex side of an integrated VR headset is shown in FIG. 19. For a heater area of 3 cm², 1.75 W can be efficiently dissipated using a front cover made from an 800 micrometer thick ultra-high molecular weight polyethylene layer having an in-plane thermal conductivity of approximately 30 W/mK.

Referring to FIG. 20, shown is a plot of maximum temperature difference versus thermal conductivity for opposing surfaces of ultra-high molecular weight polyethylene substrates exposed to an input heat flux of approximately 0.33 W/cm² (power of 1 W over a surface area of 3 cm²), where the solid lines are ΔTₘₐₓ measured on the convex side and the dashed lines are ΔTₘₐₓ measured on the concave side of the headset front cover. In this model, the out-of-plane thermal conductivity is set to 0.03, 0.1, or 0.3, while the in-plane thermal conductivity is isotropic. No appreciable effect of the out-of-plane thermal conductivity is observed for the temperature measured on the convex side.

A compression molding technique may be used to thermoform and consolidate plural ultra-high molecular weight polyethylene thin films (thickness ˜50 micrometers) into a thicker composite. The elastic modulus was measured for consolidated 8-ply samples pressed at different temperatures and pressures and for different times. According to some embodiments, a consolidation temperature may be less than approximately 135° C. (e.g., 110° C., 125° C., or 135° C., including ranges between any of the foregoing values), a consolidation pressure may be at least approximately 1.5 kpsi (e.g., 1.5, 3, 6, 9, or 12 kpsi, including ranges between any of the foregoing values), and a soak time may be less than approximately 3 min (e.g., 1, 2, or 3 min, including ranges between any of the foregoing values).

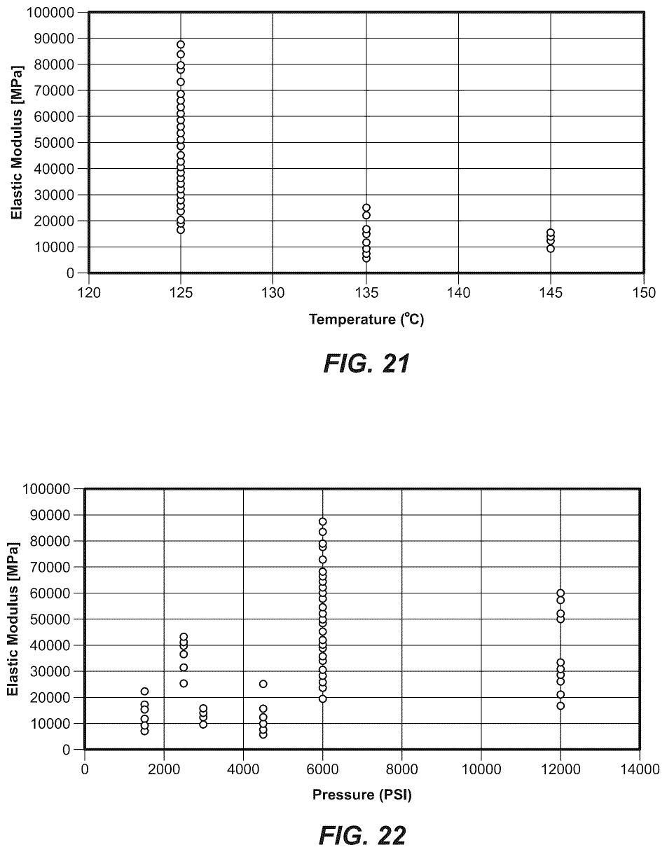

FIG. 21 is a plot of elastic modulus versus consolidation temperature for 8-ply unidirectional UHMWPE stacks. Without wishing to be bound by theory, the mechanical properties may be significantly affected for a consolidation temperature greater than approximately 135° C. irrespective of the pressure and the soak time.

FIG. 22 is a plot of elastic modulus versus consolidation pressure for 8-ply unidirectional UHMWPE stacks. Improvement in the elastic modulus may be correlated to a compression molding process having a consolidation temperature of less than approximately 125° C., a consolidation pressure of from approximately 6 kpsi to approximately 12 kpsi, and a soak time of less than approximately 1 min.

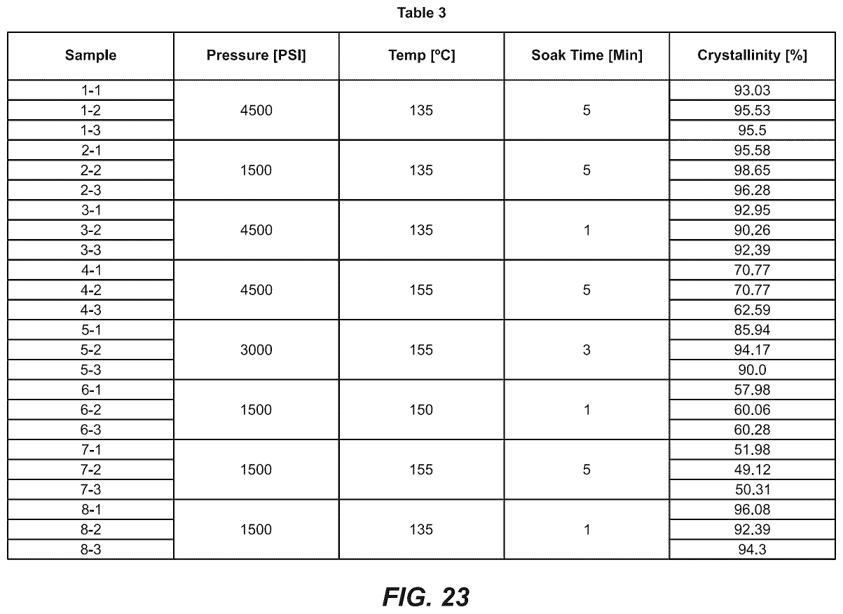

Referring to FIG. 23, tabulated are differential scanning calorimetry (DSC) data for consolidated 8-ply UHMWPE stacks for different consolidation temperatures, pressures, and soak times. The data show that consolidation temperatures greater than approximately 150° C. may cause a substantial decrease in crystallinity irrespective of the consolidation pressure and soak time.

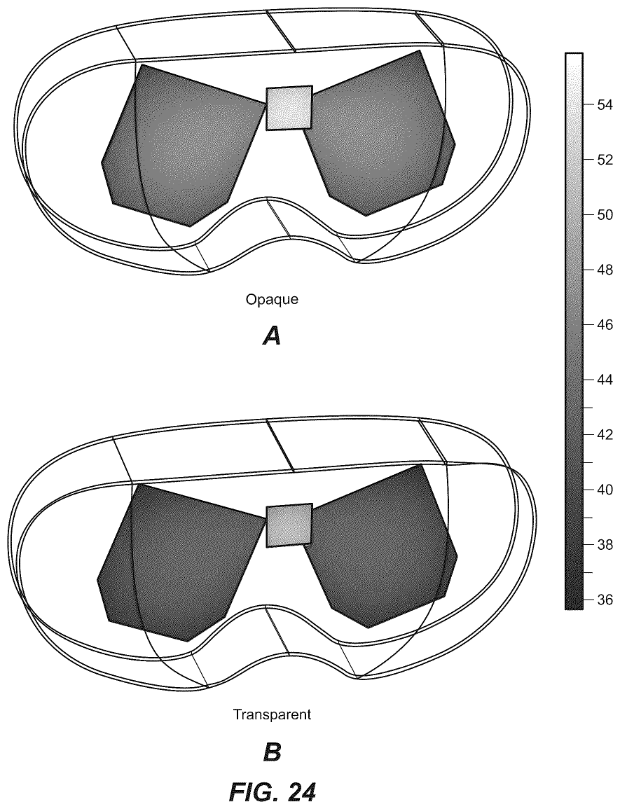

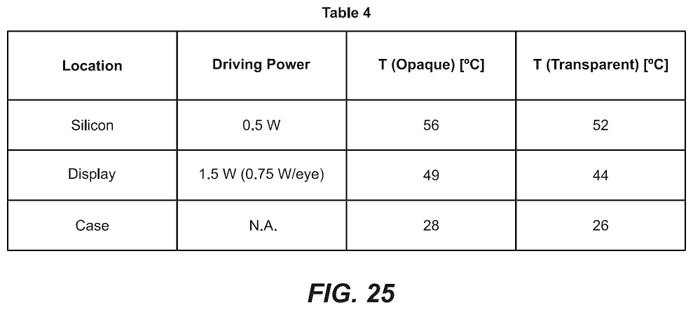

Referring to FIG. 24, shown are simulations of the thermal response for different headset enclosures comparing an IR opaque assembly with an IR transparent assembly. Heat sources are modeled as the silicon and the display with driving powers of 0.5 W, and 0.75 W/eye, respectively. Maximum temperatures on the silicon, display panel, and the case are summarized in the Table of FIG. 25. As will be appreciated, a lower display temperature may be correlated with an IR transparent enclosure.

As disclosed herein, thermally conductive and RF transparent polymer multilayer includes two or more ultra-high molecular weight polyethylene (UHMWPE) thin films. Each polyethylene thin film may be pre-stretched and oriented to provide a multilayer having desired thermal, mechanical, and optical properties. For instance, the polyethylene thin films may be stretched to a draw ratio of at least approximately 20, oriented, laid-up, and laminated to form a multilayer having a thickness of at least approximately 50 micrometers. In certain embodiments, within the multilayer, an adhesive layer may be disposed between adjacent UHMWPE thin films. Example adhesive layers include powdered UHMWPE, a polyethylene thin film, a polystyrene block copolymer, and the like.

Each UHMWPE thin film may have a thickness of at least approximately 20 micrometers, may be electrically insulating with a dielectric constant of less than approximately 3.5 (e.g., 3, 2.5, 2.2, or 2.0, including ranges between any of the foregoing values) and a loss tangent of less than approximately 0.01 (e.g., 0.005, 0.001, 0.0005, including ranges between any of the foregoing values), and may have in-plane properties including a thermal conductivity of at least approximately 5 W/mK and an elastic modulus of at least approximately 20 GPa. An example multilayer may additionally include a highly emissive layer disposed over a major surface.

According to some embodiments, a polymer laminate may be sandwiched between layers of a secondary polymer. For instance, in-deco molding, in-mold lamination (IML), or in-mold decoration (IMD) techniques may be used to partially or wholly envelop a polymer laminate between layers of an olefin polymer, such as a cyclic olefin polymer (COP) or a cyclic olefin co-polymer (COC).

Ultra-high molecular weight polyethylene multilayers may form or be incorporated into VR/AR/MR components, such as the temple arm or frame of a pair of AR glasses, or a headset chassis, front cover, or even the entire enclosure of a VR/MR headset, and may be configured to dissipate heat through convection and/or radiation in order to improve user comfort without adversely affecting performance.

In some applications, a system or device, such as an eyewear device, may include a thermal conduit such as a thermally conductive layer that is configured to conduct heat from a heat source within the device to the polymer laminate that, in turn, may be configured to disperse and/or dissipate the heat. A thermal conduit may include a layer or a strip of a metal or graphene, for example. According to some embodiments, the thermal conduit may be in physical contact with both the heat source and the polymer laminate.

### EXAMPLE EMBODIMENTS

Example 1: A polymer laminate includes a plurality of ultra-high molecular weight polyethylene thin films, where each polyethylene thin film has transmissivity within the visible spectrum of at least approximately 85%, less than approximately 5% bulk haze, an in-plane thermal conductivity of at least approximately 5 W/mK, and an in-plane elastic modulus of at least approximately 20 GPa.

Example 2: The polymer laminate of Example 1, where the polyethylene in each thin film has a weight average molecular weight of at least approximately 300,000 g/mol.

Example 3: The polymer laminate of any of Examples 1 and 2, where each polyethylene thin film has a thickness of at least approximately 20 micrometers.

Example 4: The polymer laminate of any of Examples 1-3, where each polyethylene thin film has a dielectric constant of less than approximately 3.5 and a loss tangent of less than approximately 0.01.

Example 5: The polymer laminate of any of Examples 1-4, where each polyethylene thin film has a specific resistivity of at least approximately 10¹⁰ ohm/cm.

Example 6: The polymer laminate of any of Examples 1-5, where each polyethylene thin film has an RF transparency of at least approximately 85%.

Example 7: The polymer laminate of any of Examples 1-6, where at least two of the polyethylene thin films are mutually misoriented by an in-plane angle of at least approximately 2°.

Example 8: The polymer laminate of any of Examples 1-7, where a pair of neighboring polyethylene thin films are mutually misoriented by an in-plane angle of at least approximately 2°.

Example 9: The polymer laminate of any of Examples 1-8, further including an adhesive layer disposed between neighboring polyethylene thin films.

Example 10: The polymer laminate of Example 9, where the adhesive layer includes a material selected from powdered UHMWPE, a polyethylene thin film, and a polystyrene block copolymer thin film.

Example 11: An eyewear device including the polymer laminate of any of Examples 1-10.

Example 12: The eyewear device of Example 11, where the polymer laminate is disposed over an inner surface of a viewing area of the eyewear device.

Example 13: A method includes producing an in-plane strain within first and second polyethylene thin films in an amount effective to re-orient crystals or align polyethylene chains within each polyethylene thin film and form first and second anisotropic polyethylene thin films each having an in-plane thermal conductivity of at least approximately 5 W/mK and an in-plane elastic modulus of at least approximately 20 GPa, and adhering the first anisotropic polyethylene thin film to the second anisotropic polyethylene thin film to form a polymer laminate.

Example 14: The method of Example 13, where producing the in-plane strain includes applying a uniaxial stress to at least one of the first and second polyethylene thin films.

Example 15: The method of any of Examples 13 and 14, where producing the in-plane strain includes applying a biaxial stress to at least one of the first and second polyethylene thin films.

Example 16: The method of any of Examples 13-15, where producing the in-plane strain includes stretching the first polyethylene thin film and the second polyethylene thin film each to a draw ratio of at least approximately 20.

Example 17: The method of any of Examples 13-16, further including forming the polymer laminate over a region of an eyewear device, the region being selected from a viewing area, a temple arm, a frame, a headset chassis, a front cover, and an enclosure of the eyewear device.

Example 18: A polymer laminate includes a first layer including polyethylene having a molecular weight of at least approximately 300,000 g/mol and a second layer bonded to the first layer, the second layer including polyethylene having a molecular weight of at least approximately 300,000 g/mol, where the polymer laminate has a thermal conductivity of at least approximately 5 W/mK and an elastic modulus of at least approximately 20 GPa.

Example 19: The polymer laminate of Example 18, having a specific resistivity of at least approximately 10¹⁰ ohm/cm.

Example 20: The polymer laminate of any of Examples 18 and 19, having an RF transparency of at least approximately 85%.

Example 21: The polymer laminate of any of Examples 18-20, where the first layer includes a woven or knit fibrous mat.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

Artificial-reality systems may be implemented in a variety of different form factors and configurations. Some artificial-reality systems may be designed to work without near-eye displays (NEDs). Other artificial-reality systems may include an NED that also provides visibility into the real world (such as, e.g., augmented-reality system 2600 in FIG. 26) or that visually immerses a user in an artificial reality (such as, e.g., virtual-reality system 2700 in FIG. 27). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 26, augmented-reality system 2600 may include an eyewear device 2602 with a frame 2610 configured to hold a left display device 2615(A) and a right display device 2615(B) in front of a user's eyes. Display devices 2615(A) and 2615(B) may act together or independently to present an image or series of images to a user. While augmented-reality system 2600 includes two displays, embodiments of this disclosure may be implemented in augmented-reality systems with a single NED or more than two NEDs.

In some embodiments, augmented-reality system 2600 may include one or more sensors, such as sensor 2640. Sensor 2640 may generate measurement signals in response to motion of augmented-reality system 2600 and may be located on substantially any portion of frame 2610. Sensor 2640 may represent one or more of a variety of different sensing mechanisms, such as a position sensor, an inertial measurement unit (IMU), a depth camera assembly, a structured light emitter and/or detector, or any combination thereof. In some embodiments, augmented-reality system 2600 may or may not include sensor 2640 or may include more than one sensor. In embodiments in which sensor 2640 includes an IMU, the IMU may generate calibration data based on measurement signals from sensor 2640. Examples of sensor 2640 may include, without limitation, accelerometers, gyroscopes, magnetometers, other suitable types of sensors that detect motion, sensors used for error correction of the IMU, or some combination thereof.

In some examples, augmented-reality system 2600 may also include a microphone array with a plurality of acoustic transducers 2620(A)-2620(J), referred to collectively as acoustic transducers 2620. Acoustic transducers 2620 may represent transducers that detect air pressure variations induced by sound waves. Each acoustic transducer 2620 may be configured to detect sound and convert the detected sound into an electronic format (e.g., an analog or digital format). The microphone array in FIG. 26 may include, for example, ten acoustic transducers: 2620(A) and 2620(B), which may be designed to be placed inside a corresponding ear of the user, acoustic transducers 2620(C), 2620(D), 2620(E), 2620(F), 2620(G), and 2620(H), which may be positioned at various locations on frame 2610, and/or acoustic transducers 2620(I) and 2620(J), which may be positioned on a corresponding neckband 2605.

In some embodiments, one or more of acoustic transducers 2620(A)-(J) may be used as output transducers (e.g., speakers). For example, acoustic transducers 2620(A) and/or 2620(B) may be earbuds or any other suitable type of headphone or speaker.

The configuration of acoustic transducers 2620 of the microphone array may vary. While augmented-reality system 2600 is shown in FIG. 26 as having ten acoustic transducers 2620, the number of acoustic transducers 2620 may be greater or less than ten. In some embodiments, using higher numbers of acoustic transducers 2620 may increase the amount of audio information collected and/or the sensitivity and accuracy of the audio information. In contrast, using a lower number of acoustic transducers 2620 may decrease the computing power required by an associated controller 2650 to process the collected audio information. In addition, the position of each acoustic transducer 2620 of the microphone array may vary. For example, the position of an acoustic transducer 2620 may include a defined position on the user, a defined coordinate on frame 2610, an orientation associated with each acoustic transducer 2620, or some combination thereof.

Acoustic transducers 2620(A) and 2620(B) may be positioned on different parts of the user's ear, such as behind the pinna, behind the tragus, and/or within the auricle or fossa. Or, there may be additional acoustic transducers 2620 on or surrounding the ear in addition to acoustic transducers 2620 inside the ear canal. Having an acoustic transducer 2620 positioned next to an ear canal of a user may enable the microphone array to collect information on how sounds arrive at the ear canal. By positioning at least two of acoustic transducers 2620 on either side of a user's head (e.g., as binaural microphones), augmented-reality device 2600 may simulate binaural hearing and capture a 3D stereo sound field around about a user's head. In some embodiments, acoustic transducers 2620(A) and 2620(B) may be connected to augmented-reality system 2600 via a wired connection 2630, and in other embodiments acoustic transducers 2620(A) and 2620(B) may be connected to augmented-reality system 2600 via a wireless connection (e.g., a BLUETOOTH connection). In still other embodiments, acoustic transducers 2620(A) and 2620(B) may not be used at all in conjunction with augmented-reality system 2600.

Acoustic transducers 2620 on frame 2610 may be positioned in a variety of different ways, including along the length of the temples, across the bridge, above or below display devices 2615(A) and 2615(B), or some combination thereof. Acoustic transducers 2620 may also be oriented such that the microphone array is able to detect sounds in a wide range of directions surrounding the user wearing the augmented-reality system 2600. In some embodiments, an optimization process may be performed during manufacturing of augmented-reality system 2600 to determine relative positioning of each acoustic transducer 2620 in the microphone array.

In some examples, augmented-reality system 2600 may include or be connected to an external device (e.g., a paired device), such as neckband 2605. Neckband 2605 generally represents any type or form of paired device. Thus, the following discussion of neckband 2605 may also apply to various other paired devices, such as charging cases, smart watches, smart phones, wrist bands, other wearable devices, hand-held controllers, tablet computers, laptop computers, other external compute devices, etc.

As shown, neckband 2605 may be coupled to eyewear device 2602 via one or more connectors. The connectors may be wired or wireless and may include electrical and/or non-electrical (e.g., structural) components. In some cases, eyewear device 2602 and neckband 2605 may operate independently without any wired or wireless connection between them. While FIG. 26 illustrates the components of eyewear device 2602 and neckband 2605 in example locations on eyewear device 2602 and neckband 2605, the components may be located elsewhere and/or distributed differently on eyewear device 2602 and/or neckband 2605. In some embodiments, the components of eyewear device 2602 and neckband 2605 may be located on one or more additional peripheral devices paired with eyewear device 2602, neckband 2605, or some combination thereof.

Pairing external devices, such as neckband 2605, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 2600 may be provided by a paired device or shared between a paired device and an eyewear device, thus reducing the weight, heat profile, and form factor of the eyewear device overall while still retaining desired functionality. For example, neckband 2605 may allow components that would otherwise be included on an eyewear device to be included in neckband 2605 since users may tolerate a heavier weight load on their shoulders than they would tolerate on their heads. Neckband 2605 may also have a larger surface area over which to diffuse and disperse heat to the ambient environment. Thus, neckband 2605 may allow for greater battery and computation capacity than might otherwise have been possible on a stand-alone eyewear device. Since weight carried in neckband 2605 may be less invasive to a user than weight carried in eyewear device 2602, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 2605 may be communicatively coupled with eyewear device 2602 and/or to other devices. These other devices may provide certain functions (e.g., tracking, localizing, depth mapping, processing, storage, etc.) to augmented-reality system 2600. In the embodiment of FIG. 26, neckband 2605 may include two acoustic transducers (e.g., 2620(I) and 2620(J)) that are part of the microphone array (or potentially form their own microphone subarray). Neckband 2605 may also include a controller 2625 and a power source 2635.

Acoustic transducers 2620(I) and 2620(J) of neckband 2605 may be configured to detect sound and convert the detected sound into an electronic format (analog or digital). In the embodiment of FIG. 26, acoustic transducers 2620(I) and 2620(J) may be positioned on neckband 2605, thereby increasing the distance between the neckband acoustic transducers 2620(I) and 2620(J) and other acoustic transducers 2620 positioned on eyewear device 2602. In some cases, increasing the distance between acoustic transducers 2620 of the microphone array may improve the accuracy of beamforming performed via the microphone array. For example, if a sound is detected by acoustic transducers 2620(C) and 2620(D) and the distance between acoustic transducers 2620(C) and 2620(D) is greater than, e.g., the distance between acoustic transducers 2620(D) and 2620(E), the determined source location of the detected sound may be more accurate than if the sound had been detected by acoustic transducers 2620(D) and 2620(E).

Controller 2625 of neckband 2605 may process information generated by the sensors on neckband 2605 and/or augmented-reality system 2600. For example, controller 2625 may process information from the microphone array that describes sounds detected by the microphone array. For each detected sound, controller 2625 may perform a direction-of-arrival (DOA) estimation to estimate a direction from which the detected sound arrived at the microphone array. As the microphone array detects sounds, controller 2625 may populate an audio data set with the information. In embodiments in which augmented-reality system 2600 includes an inertial measurement unit, controller 2625 may compute all inertial and spatial calculations from the IMU located on eyewear device 2602. A connector may convey information between augmented-reality system 2600 and neckband 2605 and between augmented-reality system 2600 and controller 2625. The information may be in the form of optical data, electrical data, wireless data, or any other transmittable data form. Moving the processing of information generated by augmented-reality system 2600 to neckband 2605 may reduce weight and heat in eyewear device 2602, making it more comfortable to the user.

Power source 2635 in neckband 2605 may provide power to eyewear device 2602 and/or to neckband 2605. Power source 2635 may include, without limitation, lithium ion batteries, lithium-polymer batteries, primary lithium batteries, alkaline batteries, or any other form of power storage. In some cases, power source 2635 may be a wired power source. Including power source 2635 on neckband 2605 instead of on eyewear device 2602 may help better distribute the weight and heat generated by power source 2635.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 2700 in FIG. 27, that mostly or completely covers a user's field of view. Virtual-reality system 2700 may include a front rigid body 2702 and a band 2704 shaped to fit around a user's head. Virtual-reality system 2700 may also include output audio transducers 2706(A) and 2706(B). Furthermore, while not shown in FIG. 27, front rigid body 2702 may include one or more electronic elements, including one or more electronic displays, one or more inertial measurement units (IMUS), one or more tracking emitters or detectors, and/or any other suitable device or system for creating an artificial-reality experience.

Artificial-reality systems may include a variety of types of visual feedback mechanisms. For example, display devices in augmented-reality system 2600 and/or virtual-reality system 2700 may include one or more liquid crystal displays (LCDs), light emitting diode (LED) displays, microLED displays, organic LED (OLED) displays, digital light project (DLP) micro-displays, liquid crystal on silicon (LCoS) micro-displays, and/or any other suitable type of display screen. These artificial-reality systems may include a single display screen for both eyes or may provide a display screen for each eye, which may allow for additional flexibility for varifocal adjustments or for correcting a user's refractive error. Some of these artificial-reality systems may also include optical subsystems having one or more lenses (e.g., conventional concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial-reality systems described herein may include one or more projection systems. For example, display devices in augmented-reality system 2600 and/or virtual-reality system 2700 may include microLED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

The artificial-reality systems described herein may also include various types of computer vision components and subsystems. For example, augmented-reality system 2600 and/or virtual-reality system 2700 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

The artificial-reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial-reality systems described herein may also include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

As used herein, the term “approximately” in reference to a particular numeric value or range of values may, in certain embodiments, mean and include the stated value as well as all values within 10% of the stated value. Thus, by way of example, reference to the numeric value “50” as “approximately 50” may, in certain embodiments, include values equal to 50±5, i.e., values within the range 45 to 55.

As used herein, the term “substantially” in reference to a given parameter, property, or condition may mean and include to a degree that one of ordinary skill in the art would understand that the given parameter, property, or condition is met with a small degree of variance, such as within acceptable manufacturing tolerances. By way of example, depending on the particular parameter, property, or condition that is substantially met, the parameter, property, or condition may be at least approximately 90% met, at least approximately 95% met, or even at least approximately 99% met.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

It will be understood that when an element such as a layer or a region is referred to as being formed on, deposited on, or disposed “on” or “over” another element, it may be located directly on at least a portion of the other element, or one or more intervening elements may also be present. In contrast, when an element is referred to as being “directly on” or “directly over” another element, it may be located on at least a portion of the other element, with no intervening elements present.

While various features, elements or steps of particular embodiments may be disclosed using the transitional phrase “comprising,” it is to be understood that alternative embodiments, including those that may be described using the transitional phrases “consisting of” or “consisting essentially of,” are implied. Thus, for example, implied alternative embodiments to a polymer thin film that comprises or includes polyethylene include embodiments where a polymer thin film consists essentially of polyethylene and embodiments where a polymer thin film consists of polyethylene.

What is claimed is:

1. A polymer laminate comprising a plurality of ultra-high molecular weight polyethylene thin films, wherein each polyethylene thin film comprises:
transmissivity within the visible spectrum of at least approximately 85%;
less than approximately 5% bulk haze;
an in-plane thermal conductivity of at least approximately 5 W/mK; and
an in-plane elastic modulus of at least approximately 20 GPa.

2. The polymer laminate of claim 1, wherein the polyethylene in each thin film has a weight average molecular weight of at least approximately 300,000 g/mol.

3. The polymer laminate of claim 1, wherein each polyethylene thin film has a thickness of at least approximately 20 micrometers.

4. The polymer laminate of claim 1, wherein each polyethylene thin film has a dielectric constant of less than approximately 3.5 and a loss tangent of less than approximately 0.01.

5. The polymer laminate of claim 1, wherein each polyethylene thin film has a specific resistivity of at least approximately 10¹⁰ ohm/cm.

6. The polymer laminate of claim 1, wherein each polyethylene thin film has an RF transparency of at least approximately 80%.

7. The polymer laminate of claim 1, wherein at least two of the polyethylene thin films are mutually misoriented by an in-plane angle of at least approximately 2°.

8. The polymer laminate of claim 1, wherein a pair of neighboring polyethylene thin films are mutually misoriented by an in-plane angle of at least approximately 2°.

9. The polymer laminate of claim 1, further comprising an adhesive layer disposed between neighboring polyethylene thin films.

10. The polymer laminate of claim 9, wherein the adhesive layer comprises a material selected from the group consisting of powdered UHMWPE, a polyethylene thin film, and a polystyrene block copolymer thin film.

11. An eyewear device comprising the polymer laminate of claim 1.

12. The eyewear device of claim 11, wherein the polymer laminate is disposed over an inner surface of a viewing area of the eyewear device.

13. A method comprising:
producing an in-plane strain within first and second polyethylene thin films in an amount effective to re-orient crystals or align polyethylene chains within each polyethylene thin film and form first and second anisotropic polyethylene thin films each having an in-plane thermal conductivity of at least approximately 5 W/mK and an in-plane elastic modulus of at least approximately 20 GPa; and
adhering the first anisotropic polyethylene thin film to the second anisotropic polyethylene thin film to form a polymer laminate.

14. The method of claim 13, wherein producing the in-plane strain comprises applying a uniaxial stress to at least one of the first and second polyethylene thin films.

15. The method of claim 13, wherein producing the in-plane strain comprises applying a biaxial stress to at least one of the first and second polyethylene thin films.

16. The method of claim 13, wherein producing the in-plane strain comprises stretching the first polyethylene thin film and the second polyethylene thin film each to a draw ratio of at least approximately 20.

17. The method of claim 13, further comprising forming the polymer laminate over a region of an eyewear device, the region being selected from the group consisting of a viewing area, a temple arm, a frame, a headset chassis, a front cover, and an enclosure of the eyewear device.

18. A polymer laminate comprising:
a first layer comprising polyethylene having a molecular weight of at least approximately 300,000 g/mol; and
a second layer bonded to the first layer, the second layer comprising polyethylene having a molecular weight of at least approximately 300,000 g/mol, wherein the polymer laminate comprises a thermal conductivity of at least approximately 5 W/mK, and an elastic modulus of at least approximately 20 GPa.

19. The polymer laminate of claim 18, comprising a specific resistivity of at least approximately 10¹⁰ ohm/cm.

20. The polymer laminate of claim 18, comprising an RF transparency of at least approximately 80%.
